(19) United States
(12) Patent Application Publication
(10) Pub. No.: US 2012/0305999 A1
(43) Pub. Date: Dec. 6, 2012

(54) SEMICONDUCTOR DEVICE AND METHOD OF MANUFACTURING THE SAME

(75) Inventor: Kensuke OKONOGI, Tokyo (JP)

(73) Assignee: ELPIDA MEMORY, INC., Tokyo (JP)

(21) Appl. No.: 13/485,335

(22) Filed: May 31, 2012

(30) Foreign Application Priority Data
May 31, 2011 (JP) 2011-122634

(51) Int. Cl. H01L 29/78; H01L 21/8242; H01L 27/06

(52) U.S. Cl. 257/306; 257/334; 438/239; 257/E27.016; 257/E29.262; 257/E21.648

(57) ABSTRACT

Provided are a semiconductor device capable of increasing an ON current with a reduced channel resistance, and also capable of stably and independently operating respective transistors, and a method of manufacturing the semiconductor device. A semiconductor device includes a fin portion located in a manner that a part of an active region protrudes from a bottom portion of a gate groove, a gate insulating film for covering the gate groove and a surface of the fin portion, a gate electrode which is embedded within a lower portion of the gate groove and formed so as to straddle the fin portion via the gate insulating film, a first diffusion region, a second diffusion region, and a carrier capture region provided in the surface of the fin portion.

This application is based upon and claims the benefit of priority from Japanese patent application No. 2011-122634, filed on May 31, 2011, the disclosure of which is incorporated herein in its entirety by reference.

### BACKGROUND OF THE INVENTION

1. Field of the Invention

This invention relates to a semiconductor device and a method of manufacturing the same.

2. Description of the Related Art

In recent years, a semiconductor device such as a dynamic random access memory (DRAM) is becoming smaller and smaller. As a result, a short channel effect of the transistor conspicuously appears as a gate length of a transistor becomes short. This brings about a problem of lowering a threshold voltage (Vt) of the transistor due to an increase of a subthreshold current.

In order to suppress reducing the threshold voltage (Vt) of the transistor, when an impurity concentration of a semiconductor substrate becomes dense, there is the problem that the junction leakage current is increased.

Therefore, when a dynamic random access memory (DRAM) is used as a semiconductor device and a memory cell of the DRAM is miniaturized, a serious problem takes place about deterioration of the refresh characteristics.

As structures for avoiding such problems, Japanese Unexamined Patent Application Publication (JP-A) Nos. 2006-339476 and 2007-081095 disclose a so-called trench gate transistor (also referred to as “recess channel transistor”) in which a gate electrode is embedded into a groove formed on a main surface side of the semiconductor substrate.

When the transistor is structured by a trench gate transistor, it is possible to physically and sufficiently maintain an effective channel length (gate length) and to implement a DRAM structured by a fine cell which has a feature size of 60 nm or less.

Further, Japanese Unexamined Patent Application Publication (JP-A) No. 2007-081095 discloses a DRAM which has two grooves adjacent to each other in a semiconductor substrate, gate electrodes formed in the respective grooves through gate insulating films, and a first diffusion region which is formed in a main surface of a semiconductor substrate and is located between the two gate electrodes. In this event, the first diffusion region is used as an diffusion region common to the two gate electrodes. Furthermore, the illustrated DRAM has second diffusion regions which are formed in the main surface of the semiconductor substrate and which are located adjacent to isolation regions of the two gate electrodes.

In the DRAM having the trench gate transistor described in Japanese Unexamined Patent Application Publication (JP-A) No. 2006-339476 or 2007-081095, channel regions of the transistor are formed on three surfaces of a trench, namely, both side surfaces and a bottom surface of the trench.

The inventor of this invention has found out that further advance of miniaturization in the transistor of the above-mentioned structure made it difficult to sufficiently keep an ON current of the transistor and to normally operate the DRAM. This results from the fact that channel resistance becomes high due to the transistor channel regions formed on the three surfaces of the trench, as described above.

Further, there is the problem that each transistor could not be stably operated independently with a reduction of an arrangement pitch of trench gates when each transistor was operated. This is because the operation state of each transistor interfered with that of another transistor adjacent to each transistor.

This problem also might result from an adverse effect of forming the channel regions between adjacent trench gates.

Further, the trench gate transistor has the gate electrode which is protruded upwards from the surface of the semiconductor substrate. The protruded gate electrode structure makes it difficult to form bit wiring, to form a capacitor in a following step, and, as a result, to manufacture the DRAM itself.

Therefore, even with regard to a DRAM including a transistor which uses a trench, it is desirable to obtain a semiconductor device such that a sufficient ON current of a transistor can be kept without any operation interference between adjacent transistors and to obtain a method of manufacturing the semiconductor device without any difficulties in the manufacture.

### SUMMARY OF THE INVENTION

According to this invention, there is provided a semiconductor device comprising: a semiconductor substrate; a plurality of first isolation regions which are formed in the semiconductor substrate and extended in a first direction and each of which defines an active region having a plurality of element regions; a gate groove which is provided in a surface of the semiconductor substrate and extended in a second direction intersecting the plurality of first isolation regions and the active regions, the gate groove comprising a first side surface and a second side surface opposed to the first side surface, and a bottom portion; a fin portion formed by protruding a part of the active region from the bottom portion of the gate groove, by providing, in the gate groove, a first groove portion formed in the active region and a second groove portion which is formed in the first isolation regions and which is deeper than the first groove portion, and by making a depth of a portion of the first groove portion opposite to the second groove portion substantially flush with a depth of the second groove portion; a gate insulating film which covers the gate groove and a surface of the fin portion; a gate electrode which straddles the fin portion via the gate insulating film and which is embedded within a lower portion of the gate groove;

a first diffusion region provided in the semiconductor substrate so that the first diffusion region is located on the first side surface of each gate groove and covers an upper portion of the gate insulating film; a second diffusion region provided in the semiconductor substrate so that the second diffusion region is located on the second side surface and covers a part of the gate insulating film other than a lower end portion of the gate insulating film; and

a carrier capture region formed in the surface of the fin portion so that the carrier capture region is opposed to the gate electrode with the gate insulating film interposed between the gate electrode and the carrier capture region.

According to the semiconductor device of this invention, there is provided, in the semiconductor substrate, the first diffusion region which covers the upper portion of the gate insulating film, the upper portion being arranged on the first side surface; the second diffusion region which at least covers the part of the gate insulating film, the part being arranged on the second side surface; and the fin portion formed in a manner that the part of the active region protrudes from the bottom portion of the gate groove. With this structure, channel regions are formed on not only two surfaces, that is, the bottom portion of the gate groove and a lower portion of the first side surface but also the fin portion. Therefore, the semiconductor device can reduce channel resistance in comparison with a semiconductor device having no fin portion. This structure is also effective to sufficiently keep ON current of the transistor.

Further, another gate groove is provided on the second side surface side of the gate groove, and another transistor is arranged adjacent to the gate groove. Thus, no channel region is formed between the gate grooves. With this structure, when the arrangement pitch of the gate grooves is small and a transistor is operated, the operation state does not interfere with another transistor adjacent to the transistor, and thus, the transistors can be operated independently.

Further, through provision of the gate electrode which is arranged so as to straddle the fin portion, the gate electrode filling the lower portion of the gate groove through intermediation of the gate insulating film, and a buried insulating film which is arranged so as to fill the gate groove and which covers the upper surface of the gate electrode, the gate electrode is caused not to protrude upward from a surface of the semiconductor substrate. This structure is effective to manufacture a DRAM as the semiconductor device, because a bit line and a capacitor are easily and favorably manufactured.

### BRIEF DESCRIPTION OF THE DRAWINGS

The above features and advantages of this invention will be more apparent from the following description of certain preferred embodiments taken in conjunction with the accompanying drawings, in which:

FIG. 1 is a schematic plan view of a memory cell array provided in a semiconductor device as a first embodiment to which this invention is applied;

FIG. 2A is a sectional view of the memory cell array taken along the line A-A of FIG. 1;

FIG. 2B is a sectional view of the memory cell array taken along the line B-B of FIG. 1;

FIG. 2C is a perspective view illustrating a structure in section of a fin portion provided in a gate groove in the semiconductor device as the first embodiment to which this invention is applied;

FIG. 2D is a sectional view illustrating a structure around a gate electrode in the semiconductor device as the first embodiment to which this invention is applied;

FIG. 3A illustrates a manufacturing step (1) of the memory cell array provided in the semiconductor device as the first embodiment to which this invention is applied, and is a plan view of a region in which the memory cell array is formed;

FIG. 3B illustrates the manufacturing step (1) of the memory cell array provided in the semiconductor device as the first embodiment to which this invention is applied, and is a sectional view taken along the line A-A of the structure illustrated in FIG. 3A;

FIG. 3C illustrates the manufacturing step (1) of the memory cell array provided in the semiconductor device as the first embodiment to which this invention is applied, and is a sectional view taken along the line B-B of the structure illustrated in FIG. 3A;

FIG. 3D illustrates the manufacturing step (1) of the memory cell array provided in the semiconductor device as the first embodiment to which this invention is applied, and is a sectional view taken along the line C-C of the structure illustrated in FIG. 3A;

FIG. 4A illustrates a manufacturing step (2) of the memory cell array provided in the semiconductor device as the first embodiment to which this invention is applied, and is a plan view of a region in which the memory cell array is formed;

FIG. 4B illustrates the manufacturing step (2) of the memory cell array provided in the semiconductor device as the first embodiment to which this invention is applied, and is a sectional view taken along the line A-A of the structure illustrated in FIG. 4A;

FIG. 4C illustrates the manufacturing step (2) of the memory cell array provided in the semiconductor device as the first embodiment to which this invention is applied, and is a sectional view taken along the line B-B of the structure illustrated in FIG. 4A;

FIG. 4D illustrates the manufacturing step (2) of the memory cell array provided in the semiconductor device as the first embodiment to which this invention is applied, and is a sectional view taken along the line C-C of the structure illustrated in FIG. 4A;

FIG. 5A illustrates a manufacturing step (3) of the memory cell array provided in the semiconductor device as the first embodiment to which this invention is applied, and is a plan view of a region in which the memory cell array is formed;

FIG. 5B illustrates the manufacturing step (3) of the memory cell array provided in the semiconductor device as the first embodiment to which this invention is applied, and is a sectional view taken along the line A-A of the structure illustrated in FIG. 5A;

FIG. 5C illustrates the manufacturing step (3) of the memory cell array provided in the semiconductor device as the first embodiment to which this invention is applied, and is a sectional view taken along the line B-B of the structure illustrated in FIG. 5A;

FIG. 5D illustrates the manufacturing step (3) of the memory cell array provided in the semiconductor device as the first embodiment to which this invention is applied, and is a sectional view taken along the line C-C of the structure illustrated in FIG. 5A;

FIG. 6A illustrates a manufacturing step (4) of the memory cell array provided in the semiconductor device as the first embodiment to which this invention is applied, and is a plan view of a region in which the memory cell array is formed;

FIG. 6B illustrates the manufacturing step (4) of the memory cell array provided in the semiconductor device as the first embodiment to which this invention is applied, and is a sectional view taken along the line A-A of the structure illustrated in FIG. 6A;

FIG. 6C illustrates the manufacturing step (4) of the memory cell array provided in the semiconductor device as the first embodiment to which this invention is applied, and is a sectional view taken along the line B-B of the structure illustrated in FIG. 6A;

FIG. 6D illustrates the manufacturing step (4) of the memory cell array provided in the semiconductor device as the first embodiment to which this invention is applied, and is a sectional view taken along the line C-C of the structure illustrated in FIG. 6A;

FIG. 7A illustrates a manufacturing step (5) of the memory cell array provided in the semiconductor device as the first embodiment to which this invention is applied, and is a plan view of a region in which the memory cell array is formed;

FIG. 7B illustrates the manufacturing step (5) of the memory cell array provided in the semiconductor device as the first embodiment to which this invention is applied, and is a sectional view taken along the line A-A of the structure illustrated in FIG. 7A;

FIG. 7C illustrates the manufacturing step (5) of the memory cell array provided in the semiconductor device as the first embodiment to which this invention is applied, and is a sectional view taken along the line B-B of the structure illustrated in FIG. 7A;

FIG. 7D illustrates the manufacturing step (5) of the memory cell array provided in the semiconductor device as the first embodiment to which this invention is applied, and is a sectional view taken along the line C-C of the structure illustrated in FIG. 7A;

FIG. 8A illustrates a manufacturing step (6) of the memory cell array provided in the semiconductor device as the first embodiment to which this invention is applied, and is a plan view of a region in which the memory cell array is formed;

FIG. 8B illustrates the manufacturing step (6) of the memory cell array provided in the semiconductor device as the first embodiment to which this invention is applied, and is a sectional view taken along the line A-A of the structure illustrated in FIG. 8A;

FIG. 8C illustrates the manufacturing step (6) of the memory cell array provided in the semiconductor device as the first embodiment to which this invention is applied, and is a sectional view taken along the line B-B of the structure illustrated in FIG. 8A;

FIG. 8D illustrates the manufacturing step (6) of the memory cell array provided in the semiconductor device as the first embodiment to which this invention is applied, and is a sectional view taken along the line C-C of the structure illustrated in FIG. 8A;

FIG. 9A illustrates a manufacturing step (7) of the memory cell array provided in the semiconductor device as the first embodiment to which this invention is applied, and is a plan view of a region in which the memory cell array is formed;

FIG. 9B illustrates the manufacturing step (7) of the memory cell array provided in the semiconductor device as the first embodiment to which this invention is applied, and is a sectional view taken along the line A-A of the structure illustrated in FIG. 9A;

FIG. 9C illustrates the manufacturing step (7) of the memory cell array provided in the semiconductor device as the first embodiment to which this invention is applied, and is a sectional view taken along the line B-B of the structure illustrated in FIG. 9A;

FIG. 9D illustrates the manufacturing step (7) of the memory cell array provided in the semiconductor device as the first embodiment to which this invention is applied, and is a sectional view taken along the line C-C of the structure illustrated in FIG. 9A;

FIG. 10A illustrates a manufacturing step (8) of the memory cell array provided in the semiconductor device as the first embodiment to which this invention is applied, and is a plan view of a region in which the memory cell array is formed;

FIG. 10B illustrates the manufacturing step (8) of the memory cell array provided in the semiconductor device as the first embodiment to which this invention is applied, and is a sectional view taken along the line A-A of the structure illustrated in FIG. 10A;

FIG. 10C illustrates the manufacturing step (8) of the memory cell array provided in the semiconductor device as the first embodiment to which this invention is applied, and is a sectional view taken along the line B-B of the structure illustrated in FIG. 10A;

FIG. 10D illustrates the manufacturing step (8) of the memory cell array provided in the semiconductor device as the first embodiment to which this invention is applied, and is a sectional view taken along the line C-C of the structure illustrated in FIG. 10A;

FIG. 11A illustrates a manufacturing step (9) of the memory cell array provided in the semiconductor device as the first embodiment to which this invention is applied, and is a plan view of a region in which the memory cell array is formed;

FIG. 11B illustrates the manufacturing step (9) of the memory cell array provided in the semiconductor device as the first embodiment to which this invention is applied, and is a sectional view taken along the line A-A of the structure illustrated in FIG. 11A,

FIG. 11C illustrates the manufacturing step (9) of the memory cell array provided in the semiconductor device as the first embodiment to which this invention is applied, and is a sectional view taken along the line B-B of the structure illustrated in FIG. 11A;

FIG. 11D illustrates the manufacturing step (9) of the memory cell array provided in the semiconductor device as the first embodiment to which this invention is applied, and is a sectional view taken along the line C-C of the structure illustrated in FIG. 11A;

FIG. 12A illustrates a manufacturing step (10) of the memory cell array provided in the semiconductor device as the first embodiment to which this invention is applied, and is a plan view of a region in which the memory cell array is formed;

FIG. 12B illustrates the manufacturing step (10) of the memory cell array provided in the semiconductor device as the first embodiment to which this invention is applied, and is a sectional view taken along the line A-A of the structure illustrated in FIG. 12A;

FIG. 12C illustrates the manufacturing step (10) of the memory cell array provided in the semiconductor device as the first embodiment to which this invention is applied, and is a sectional view taken along the line B-B of the structure illustrated in FIG. 12A;

FIG. 13A illustrates a manufacturing step (11) of the memory cell array provided in the semiconductor device as the first embodiment to which this invention is applied, and is a plan view of a region in which the memory cell array is formed;

FIG. 13B illustrates the manufacturing step (11) of the memory cell array provided in the semiconductor device as the first embodiment to which this invention is applied, and is a sectional view taken along the line A-A of the structure illustrated in FIG. 13A;

FIG. 13C illustrates the manufacturing step (11) of the memory cell array provided in the semiconductor device as the first embodiment to which this invention is applied, and is a sectional view taken along the line B-B of the structure illustrated in FIG. 13A;

FIG. 14A illustrates a manufacturing step (12) of the memory cell array provided in the semiconductor device as the first embodiment to which this invention is applied, and is a plan view of a region in which the memory cell array is formed;

FIG. 14B illustrates the manufacturing step (12) of the memory cell array provided in the semiconductor device as the first embodiment to which this invention is applied, and is a sectional view taken along the line A-A of the structure illustrated in FIG. 14A;

FIG. 14C illustrates the manufacturing step (12) of the memory cell array provided in the semiconductor device as the first embodiment to which this invention is applied, and is a sectional view taken along the line B-B of the structure illustrated in FIG. 14A;

FIG. 15A illustrates a manufacturing step (13) of the memory cell array provided in the semiconductor device as the first embodiment to which this invention is applied, and is a plan view of a region in which the memory cell array is formed;

FIG. 15B illustrates the manufacturing step (13) of the memory cell array provided in the semiconductor device as the first embodiment to which this invention is applied, and is a sectional view taken along the line A-A of the structure illustrated in FIG. 15A;

FIG. 15C illustrates the manufacturing step (13) of the memory cell array provided in the semiconductor device as the first embodiment to which this invention is applied, and is a sectional view taken along the line B-B of the structure illustrated in FIG. 15A;

FIG. 16A illustrates a manufacturing step (14) of the memory cell array provided in the semiconductor device as the first embodiment to which this invention is applied, and is a sectional view corresponding to a section illustrated in FIG. 2A;

FIG. 16B illustrates the manufacturing step (14) of the memory cell array provided in the semiconductor device as the first embodiment to which this invention is applied, and is a sectional view corresponding to a section illustrated in FIG. 2B;

FIG. 17A illustrates a manufacturing step (15) of the memory cell array provided in the semiconductor device as the first embodiment to which this invention is applied, and is a sectional view corresponding to the section illustrated in FIG. 2A;

FIG. 17B illustrates the manufacturing step (15) of the memory cell array provided in the semiconductor device as the first embodiment to which this invention is applied, and is a sectional view corresponding to the section illustrated in FIG. 2B;

FIG. 18A illustrates a manufacturing step (16) of the memory cell array provided in the semiconductor device as the first embodiment to which this invention is applied, and is a sectional view corresponding to the section illustrated in FIG. 2A;

FIG. 18B illustrates the manufacturing step (16) of the memory cell array provided in the semiconductor device as the first embodiment to which this invention is applied, and is a sectional view corresponding to the section illustrated in FIG. 2B;

FIG. 19A illustrates a structure of a memory cell array provided in a semiconductor device as a second embodiment to which this invention is applied, and is a sectional view taken along the line A-A of FIG. 1;

FIG. 19B illustrates the structure of the memory cell array provided in the semiconductor device as the second embodiment to which this invention is applied, and is a sectional view taken along the line B-B of FIG. 1;

FIG. 20 is a sectional view illustrating another exemplary carrier capture region which is applicable to the semiconductor device as an embodiment to which this invention is applied;

FIG. 21 is a plan view illustrating another exemplary layout of a memory cell array which is applicable to the semiconductor device as an embodiment to which this invention is applied;

FIG. 22 is a graph showing the relationship between the height of a fin portion and the fraction defective of the semiconductor device as an embodiment to which this invention is applied;

FIG. 23 is a graph showing the relationship between the depth of a second diffusion region and the fraction defective of the semiconductor device as an embodiment to which this invention is applied;

FIG. 24 is a graph showing the relationship of junction locations of respective diffusion regions of the semiconductor device as an embodiment to which this invention is applied;

FIG. 25 is a plan view illustrating an exemplary layout of a conventional DRAM; and

FIG. 26 is a sectional view taken along the line Z-Z of the DRAM illustrated in FIG. 25.

### DETAILED DESCRIPTION OF THE PREFERRED EMBODIMENTS

In general, as a memory cell of a dynamic random access memory (DRAM) becomes small in size, a distance between two adjacent cells located within a single active region also becomes short. Under the circumstances, the inventor of this invention has discovered the new phenomenon that, when there are two adjacent cells one of which holds data “zero” (“L” information) and the other of which holds data “one” (“H” information) and when the one cell holding data “zero” is continuously or repeatedly accessed, a disturbance failure (hereinafter, simply referred to as “disturb failure”) undesirably takes place between adjacent cells so that data held in another cell holding data “one” is destroyed. This disturb failure reduces reliability of the semiconductor device.

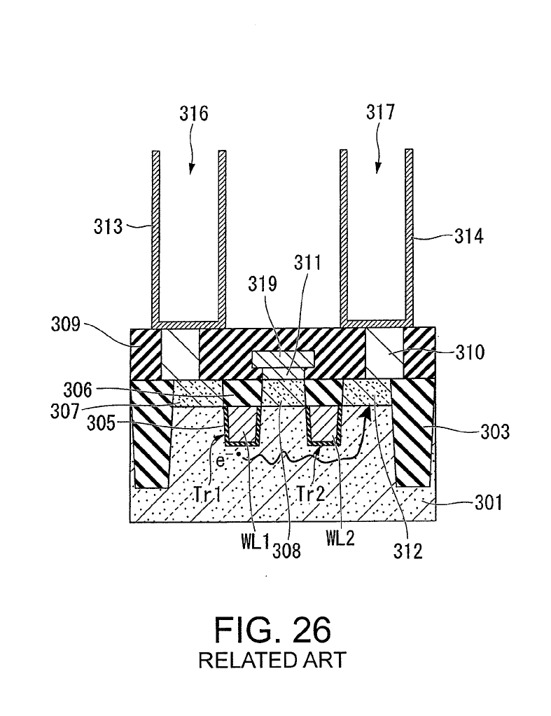

Before describing this invention, the related art will be explained in detail with reference to FIGS. 25 and 26 in order to facilitate the understanding of this invention.

FIG. 25 is a plan view illustrating an exemplary layout of a DRAM according to the related art and FIG. 26 is a sectional view taken along the line Z-Z of the DRAM illustrated in FIG. 25.

Next, description would be made with reference to FIGS. 25 and 25 about the above-mentioned disturb failure based on the new knowledge of the inventor.

With reference to FIG. 25, a semiconductor substrate 301 has a plurality of active regions 302 regularly arranged on a surface of the semiconductor substrate 301. The active regions 302 are surrounded by isolation regions 303 which have grooves formed in the surface of the semiconductor substrate 301 and insulating films embedded in the grooves. A plurality of word lines WL are arranged along a Y direction and intersect the active regions 302.

With reference to FIG. 26, the word lines WL1 and WL2 are formed so that they embed, on gate insulating films 305 (FIG. 26), grooves extended across a plurality of active regions 302 and isolation regions 303 on the surface of the semiconductor substrate 301.

A cap insulating film 306 (FIG. 26) is provided on each upper surface of the word lines WL1 and WL2 and is embedded in the grooves. The illustrated two word lines which are specified by the word line WL1 and the word line WL2 intersect the one active region 302.

The two word lines WL1 and WL2 also serve as gate electrodes of two transistors Tr1 and Tr2 illustrated in FIG. 25, respectively. The transistor Tr1 illustrated in FIG. 26 is structured by the gate electrode, namely, the word line WL1, a drain diffusion layer 307, and a source diffusion layer 308.

Likewise, the transistor Tr2 is structured by the gate electrode, namely, the word line WL2, a drain diffusion layer 312, and the source diffusion layer 308. The source diffusion layer 308 is used in common to the transistors Tr1 and Tr2, and is connected to a bit line BL (FIG. 25) at a bit line contact 311.

On the other hand, the drain diffusion layers 307 and 312 are connected to lower electrodes 313 and 314 (storage nodes) through capacitor contact plugs 310 formed through an interlayer insulating film 309, respectively.

The lower electrodes 313 and 314 form capacitor elements 316 and 317, respectively, together with capacitor insulating films and upper electrodes both of which are not shown. Channels of the transistors Tr1 and Tr2 are formed by surfaces of the semiconductor substrate 301 which correspond to bottom surfaces and two opposing side surfaces of the grooves which are embedded with the word lines WL1 and WL2, respectively.

For example, when the word line WL1 is put in an ON state and the channel of the transistor Tr1 is formed, and a potential at Low (L) level is given to the bit line 319, the lower electrode 313 is in an “L” state. Thereafter, when the word line WL1 is put in an OFF state, the information of L (data “zero”) is stored in the lower electrode 313.

In addition, for example, when the word line WL2 is put in an ON state and the channel of the transistor Tr2 is formed, and a potential at High (H) level is given to the bit line 319, the lower electrode 314 is put in an “H” state. Subsequently, when the word line WL2 is put in an OFF state, the information of H (data “one”) is stored in the lower electrode 314.

In the above-mentioned manner, a state is formed in which “L” is stored in the lower electrode 313 and “H” is stored in the lower electrode 314. In this state, it is assumed that ON/OFF operations of the word line WL1 corresponding to the lower electrode 313 (storing “L”) is repeated. These operations correspond to cell operations in other active regions which use the same word line WL1.

As a result, electrons “e⁻” induced in the channel of the transistor Tr1 reach the adjacent drain diffusion layer 312 to destroy the “H” information which is stored in the lower electrode 314 and which is changed to the “L” state.

In other words, a mode failure is caused to occur such that data “one” is changed to data “zero”. This failure occurs at a frequency depending on the number of repetition of ON/OFF operations of the word line WL1. For example, the frequency of the failure is that, when ON/OFF operations are repeated 10,000 times, information is destroyed in a single cell among the plurality of cells and, when ON/OFF operations are repeated 100,000 times, information is destroyed in ten cells.

Herein, it is to be noted that adjacent cells are essentially required to store their own information independently of each other. When a disturb failure is caused to occur such that the operation state of one of the adjacent cells changes the state of information stored or held in the other of the adjacent cells, there is a problem that normal operation of the semiconductor device (DRAM) is harmed and the reliability is lost.

The problem of the disturb failure never takes place when the cell is large in size, for example, when the distance L between the word line WL1 and the word line WL2 illustrated in FIG. 25, which is defined by the feature size F is 70 nm.

However, as the memory cell is reduced in size and the distance between the word line WL1 and the word line WL2 becomes smaller than 50 nm, the problem becomes serious. As the miniaturization progresses, the problem becomes more serious.

Exemplary embodiments to which this invention is applied would be described in detail in the following with reference to the attached drawings. It should be noted that, the drawings referred to in the following description are merely used for the purpose of describing the structures of the exemplary embodiments according to this invention, and in some cases, the sizes, thicknesses, and dimensions of the respective illustrated parts are different from the dimensional relationship in the actual semiconductor device.

### First Embodiment

### (Semiconductor Device)

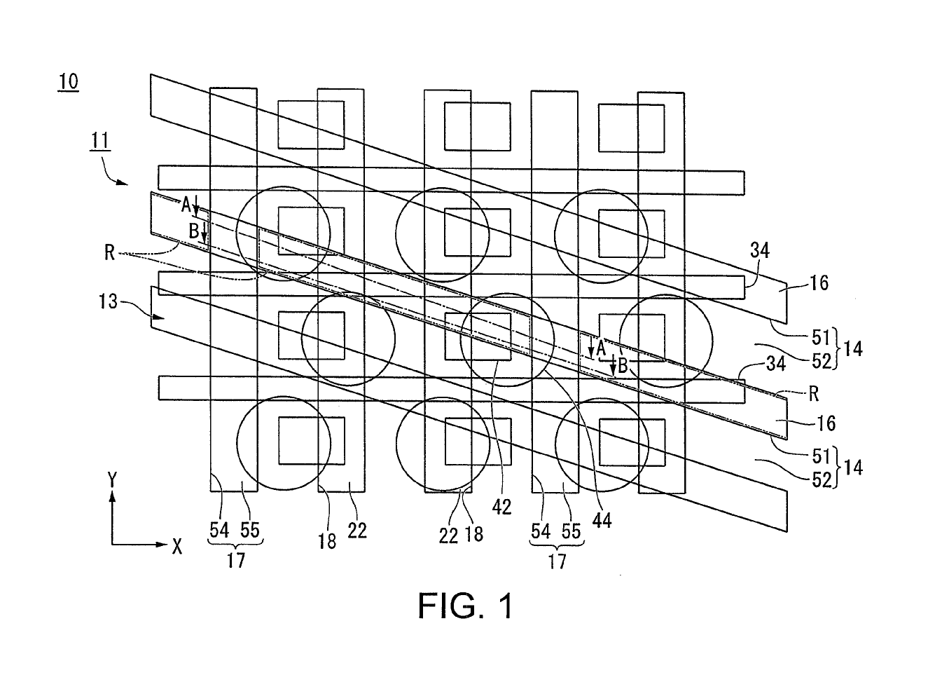

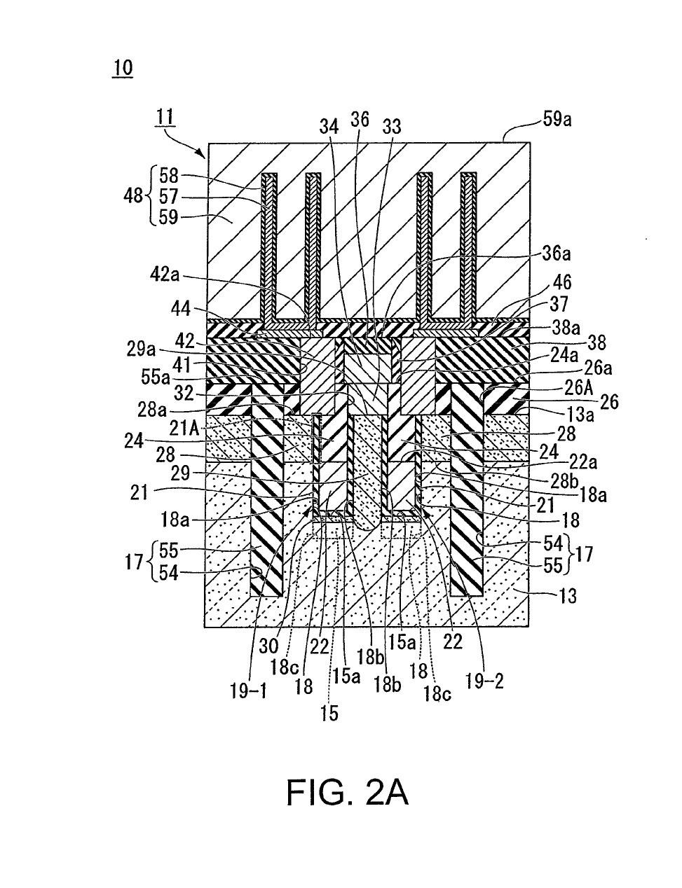

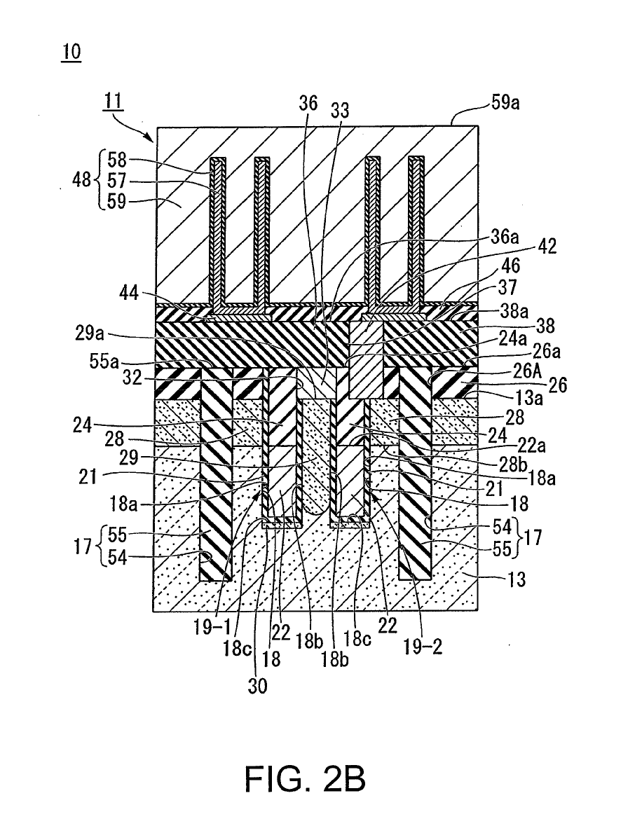

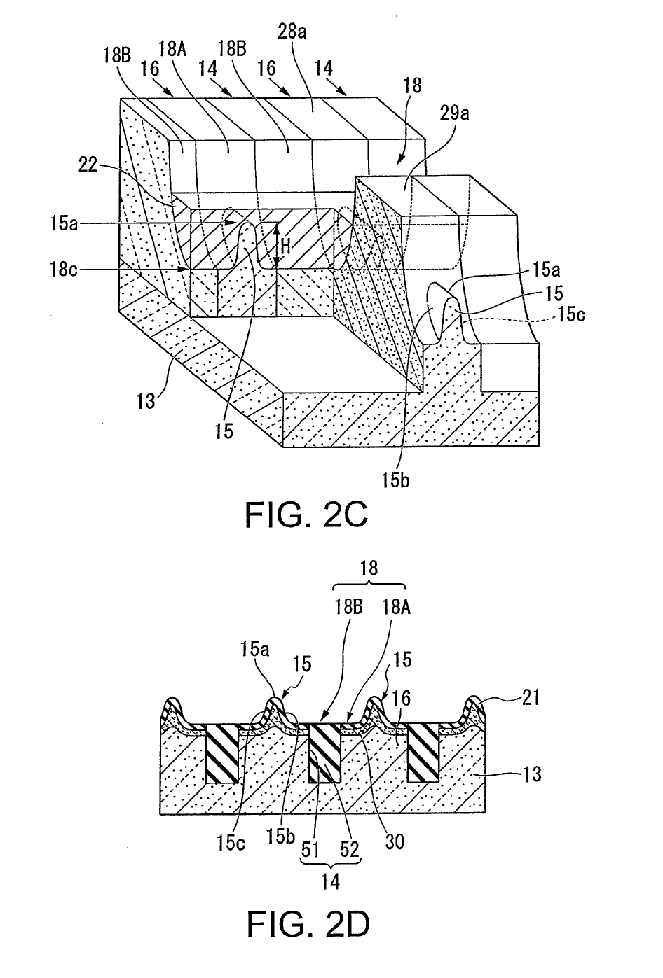

FIG. 1 is a schematic plan view of a memory cell array provided in a semiconductor device according to a first embodiment of this invention. FIG. 2A is a sectional view taken along the line A-A of the memory cell array illustrated in FIG. 1. FIG. 2B is a sectional view of the memory cell array taken along the line B-B of FIG. 1. FIG. 2C is a perspective view illustrating a structure in section of a fin portion provided in a gate groove in the semiconductor device according to the first embodiment. FIG. 2D is an enlarged view around the gate groove and the fin portion and is a sectional view illustrating an internal structure around the fin portion.

In FIG. 1, FIG. 2A, and FIG. 2B, a dynamic random access memory (DRAM) is illustrated as an example of a semiconductor device 10 as the first embodiment according to this invention. Further, FIG. 1 illustrates an exemplary layout of a memory cell array of the DRAM.

In FIG. 1, bit lines 34 extend along an X direction (first direction) while gate electrodes 22 and second isolation regions 17 extend along a Y direction (second direction) which intersect the X direction.

Further, for the sake of convenience of description, FIG. 1 illustrates, among structural components of a memory cell array 11, only a semiconductor substrate 13, first isolation regions 14, active regions 16, the second isolation regions 17, gate grooves 18, the gate electrodes 22, the bit lines 34, capacitor contact plugs 42, capacitor contact pads 44, and a plurality of element regions R. Other structural components of the memory cell array 11 are omitted from FIG. 1.

Further, FIG. 2A schematically illustrates the bit line 34 which actually extends in the X direction illustrated in FIG. 1. Further, in FIGS. 2A to 2D, like reference numerals are used to designate like or identical members of the semiconductor device 10 illustrated in FIG. 1.

The illustrated semiconductor device 10 according to the first embodiment of this invention includes a memory cell region for forming the memory cell array 11 illustrated in FIG. 1, FIG. 2A, and FIG. 2B and a peripheral circuit region (not shown) arranged on the periphery of the memory cell region (the region for a peripheral circuit).

As illustrated in FIG. 1, FIG. 2A, FIG. 2B, and FIG. 2D, the memory cell array 11 provided in the semiconductor device 10 includes the semiconductor substrate 13, the first isolation regions 14, the active regions 16 having a plurality of element regions R, the second isolation regions 17, the gate grooves 18, and a fin portion 15 (illustrated in FIGS. 2A, 2C, and 2D)) formed in a manner such that a part of the active region 16 protrudes from a bottom portion 18c of each gate groove 18, as shown in FIGS. 2C and 2D.

In addition, first and second transistors 19-1 and 19-2 are illustrated in FIGS. 2A and 2B together with gate insulating films 21, the gate electrodes 22 formed as buried gate electrodes, buried insulating films 24, a mask insulating film 26, first diffusion regions 28, a second diffusion region 29, carrier capture regions 30, an opening 32, a bit line contact plug 33, the bit line 34, a cap insulating film 36, sidewall films 37, an interlayer insulating film 38, contact holes 41, the capacitor contact plugs 42, the capacitor contact pads 44, a silicon nitride film 46, and capacitors 48.

As illustrated in FIG. 1, FIG. 2A, and FIG. 2B, the semiconductor substrate 13 is a plate-like substrate. As the semiconductor substrate 13, for example, a p-type single crystal silicon substrate may be used. In this case, the p-type impurity concentration of the semiconductor substrate 13 may be, for example, 1E16 atoms/cm².

As shown in FIG. 1, each first isolation region 14 is structured by a first isolation groove 51 and a first isolation insulating film 52. The first isolation grooves 51 are formed in the semiconductor substrate 13 and extend in a direction (first direction) which is tilted at a predetermined angle with respect to the X direction illustrated in FIG. 1. A plurality of the first isolation grooves 51 are located or arranged at predetermined intervals with respect to the Y direction illustrated in FIG. 1. A depth of each first isolation groove 51 may be, for example, 250 nm.

Each first isolation insulating film 52 is arranged so as to embed the first isolation groove 51. Although not shown in the figures, an upper surface of each first isolation insulating film 52 is flush with a main surface 13a of the semiconductor substrate 13. As each first isolation insulating film 52, for example, a silicon oxide film (SiO₂ film) may be used.

The first isolation regions 14 having the above-mentioned structure serve to isolate or define the active regions 16 which extend in the second direction in strip-shapes.

As illustrated in FIG. 1, FIG. 2A, and FIG. 2B, each of the second isolation regions 17 includes a second isolation groove 54 and a second isolation insulating film 55. The second isolation groove 54 is formed in the semiconductor substrate 13 and extends in the Y direction (second direction) illustrated in FIG. 1. Thus, each of the second isolation grooves 54 cuts a part of each first isolation region 14. The second isolation grooves 54 are formed so that two gate electrodes 22 are interleaved between two adjacent ones of the second isolation grooves 54.

Each of the gate electrodes 22 constitutes a word line of a memory cell. More specifically, in a memory cell of this embodiment, a single one of the second isolation region 17 and two gate electrodes 22 (word lines) both extending in the Y direction form a single unit and are repeatedly arranged in the X direction.

The depth of each second isolation groove 54 may be, for example, 250 nm.

Each of the second isolation insulating films 55 is arranged so as to embed each second isolation groove 54 and an opening 26A formed in the mask insulating film 26, as shown in FIGS. 2A and 2B. An upper surface 55a of each second isolation insulating film 55 is flush with an upper surface 26a of the mask insulating film 26. As the second isolation insulating films 55, for example, a silicon oxide film (SiO₂ film) may be used.

The second isolation regions 17 with the above-mentioned structure serve to partition a plurality of element regions R along the second direction Y.

Thus, each active region 16 is partitioned into the plurality of the element regions R by providing the first isolation region 14 formed by embedding the first isolation insulating film 52 into the first isolation groove 51 formed in the semiconductor substrate 13, together with the second isolation region 17 formed by embedding the second isolation insulating film 55 into the second isolation groove 54 formed in the semiconductor substrate 13. This structure is effective to easily turn on each of the first and the second transistors 19-1 and 19-2 and can improve a data holding characteristic of the memory cell array 11, in comparison with the case where a plurality of element regions are partitioned by providing gate insulating films and dummy gate electrodes (not shown) on the gate insulating films, both of which are embedded into the second element isolating grooves 54, the dummy gate electrodes being given a negative potential. This is because potentials of the dummy gate electrodes do not inversely affect the first and the second transistors 19-1 and 19-2.

As illustrated in FIG. 1, FIG. 2A, and FIG. 2B, two gate grooves 18 (in a pair) are provided in the semiconductor substrate 13 and are located between two second isolation regions 17 so as to extend in the Y direction. Each of the gate grooves 18 is defined by an inner surface including opposing first and second side surfaces 18a and 18b and the bottom portion 18c. The illustrated gate grooves 18 are arranged in pair so that the second side surfaces 18b thereof are opposed or adjacent to each other.

As illustrated in FIG. 2B and FIG. 2C, each gate groove 18 is formed so that the bottom portion 18c thereof becomes shallower than the first and second isolation grooves 51 and 54 (first and second isolation regions 14 and 17). Specifically, when each depth of the first and second isolation grooves 51 and 54 is 250 nm, it is preferred that each depth of the gate groove 18 be, for example, 150 nm to 200 nm.

As illustrated in FIG. 1, FIG. 2C, and FIG. 2D, each gate groove 18 is extended in a manner of intersecting the first isolation regions 14 and the active regions 16. More specifically, each gate groove 18 has a first groove portion 18A formed in each active region 16 and a second groove portion 18B which is formed in each first isolation region 14 and which are continuous with the first groove portion 18A.

As illustrated in FIG. 2B, FIG. 2C, and FIG. 2D, a bottom portion of the second groove portion 18B formed in each first isolation region 14 forms the bottom portion 18c of each gate groove 18. As illustrated in FIG. 2A, FIG. 2C, and FIG. 2D, an end of a bottom portion of each first groove portion 18A formed in each active region 16 of the gate grooves 18 is opposed to each second groove portion 18B. The end of the bottom portion of each first groove portion 18A has the same depth as the bottom portion of each second groove portion 18B.

On the other hand, each first groove portion 18A has a center portion which is partially protruded at each active region 16 from the bottom portion to provide the fin portion 15, as illustrated in FIG. 2C.

As illustrated in FIGS. 2A to 2D, the fin portion 15 includes an upper portion 15a, a side surface 15b, and a side surface 15c.

The upper portion 15a extends in the direction (first direction) along each active region 16. Both ends of the upper portion 15a in the extending direction reach the first side surface 18a and the second side surface 18b, respectively, which form the gate groove 18 in the first groove portion 18A.

The pair of side surfaces 15b and 15c are arranged so as to be in parallel with the direction in which each active region 16 extends (first direction).

The fin portion 15 may be shaped so that the fin portion 15 does not have an acute angle as illustrated in FIG. 2C and FIG. 2D, or the fin portion 15 may have an acute angle.

In this embodiment, the height of the fin portion 15 means the height denoted by reference symbol H in FIG. 2C, which extends in a vertical direction from the lowest portion of the bottom portion 18c of the gate groove 18 to the upper portion 15a.

It is preferable that, when the depth of each gate groove 18 is 150 nm to 200 nm, the height H of the fin portion 15 may fall within the range of 10 nm to 40 nm. In other words, it is preferable that the upper portion 15a of the fin portion 15 is located at a depth which is 100 nm deep or deeper from a surface of the semiconductor substrate 13.

When the height H of the fin portion 15 is less than 10 nm, the subthreshold factor (S factor) becomes large and the OFF leakage current increases. Further, the current driving ability is lowered and the writing characteristics are deteriorated. Therefore, the height H less than 10 nm is not preferable. On the other hand, when the height H of the fin portion 15 is higher than 40 nm, suppression of the above-mentioned disturb failure becomes inadequate. Accordingly, the height H higher than 40 nm is not preferable.

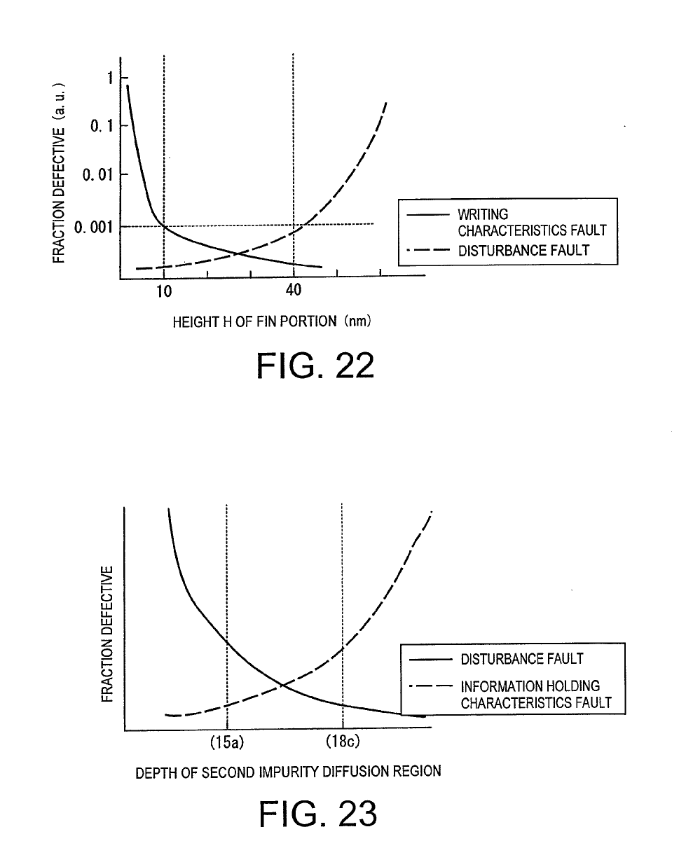

When the height H of the fin portion 15 falls within the above-mentioned range between 10 nm and 40 nm, the disturb failure may be adequately suppressed, and still, increase in the OFF leakage current may be suppressed and the writing characteristics may be improved. In other words, all the above-mentioned characteristics which have tradeoff relationships are adjusted to pertinent ranges by controlling the height of the fin portion 15, as shown in FIG. 22.

As illustrated in FIGS. 2A, 2B, and 2D, the carrier capture region 30 is provided on a surface of the fin portion 15 which underlies the gate insulating film 21 and which is opposed to the gate electrode 22 with the gate insulating film 21 interposed between the carrier capture region 30 and the fin portion 15.

In this embodiment, the carrier capture region 30 is provided in a region below the gate insulating film 21 which is located at the bottom portion of the gate groove 18 and which is provided on a surface of each active region 16 including the fin portion 15, that is, a region to be an inversion layer or a region in proximity to the inversion layer when the gate electrode 22 which is opposed across the gate insulating film 21 is in the ON state. More specifically, for example, the carrier capture region 30 is formed at a depth of 10 nm to 25 nm from the surface of each active region 16 including the fin portion 15 (which is provided with the gate insulating film 21) and has a width of 10 nm to 25 nm.

The carrier capture region 30 is formed by implanting, in the semiconductor substrate 13, ions of a capture level-formable element to be implanted. The element to be implanted is not specifically limited as long as the element is operable as a capture level-formable element, and may be, for example, carbon (C) or fluorine (F).

Thus, the carrier capture region 30 underlies the gate insulating film 21 which is provided at the bottom portion of each gate groove 18 and on the surface of each active region 16 including the fin portion 15. With this structure, it is assumed that the gate electrode 22 is opposed via the gate insulating film 21 and changes abruptly from the ON state to the OFF state. In this event, electrons accumulated in the inversion layer formed on the surface of the active region 16 operable as a gate interface are likely to be released in the semiconductor substrate 13. However, the level in the carrier capture region 30 provided in or in proximity to the inversion layer functions as a center of recombination. As a result, such electrons quickly disappear.

With reference to FIGS. 2A to 2D, the first and second transistors 19-1 and 19-2 are trench gate transistors, and each of the transistors includes the gate insulating film 21, the gate electrode 22 of a saddle fin type operable as a buried word line, the buried insulating film 24, the first diffusion region 28, and the second diffusion region 29. In addition, the carrier capture region 30 is also provided in the surface of each active region 16 including the fin portion 15.

As illustrated in FIG. 2A and FIG. 2B, the first and second transistors 19-1 and 19-2 are adjacent to each other. The second diffusion region 29 functions as a diffusion region (in the structure illustrated in FIG. 2A and FIG. 2B, a drain region) which is common to the first and second transistors 19-1 and 19-2.

More specifically, the second side surface 18b of the gate groove 18 which is included in the first transistor 19-1 is opposed to the second side surface 18b of the gate groove 18 which is included in the second transistor 19-2, with the second diffusion region 29 interposed between each second side surface 18b of the first and the second transistors 19-1 and 19-2.

With reference to FIGS. 2A to 2D, each gate insulating film 21 is provided so as to cover the first and second side surfaces 18a and 18b and the bottom portions 18c of the gate grooves 18. Further, the gate insulating film 21 also covers the surface of the fin portions 15 (that is, the upper portions 15a and the side surfaces 15b and 15c) provided at the bottom portions 18c of the gate grooves 18.

As the gate insulating film 21, for example, a single layer silicon oxide film (SiO₂ film), a film (SiON film) formed by nitriding a silicon oxide film, a multilayered silicon oxide film (SiO₂ film), a multilayered film formed by stacking a silicon nitride film (SiN film) on a silicon oxide film (SiO₂ film), or the like may be used.

When a single layer silicon oxide film (SiO₂ film) is used as the gate insulating film 21, the thickness of the gate insulating film 21 may be, for example, 6 nm.

With reference to FIGS. 2A to 2D, a saddle fin type buried word line is used as the gate electrode 22 also for the purpose of reducing the OFF leakage current and improving the writing characteristics. The saddle fin type serves to reduce the S factor and, in consequence, the threshold voltage may be lowered with the OFF leakage current maintained. Further, the saddle fin type may improve the current driving ability, and thus, the writing characteristics may be improved.

The gate electrode 22 is deposited on the gate insulating film 21 and embeds a lower portion of the gate groove 18. Therefore, the gate electrode 22 is provided so that the fin portion 15 is straddled through intermediation of the gate insulating film 21. Further, an upper surface 22a of the gate electrode 22 is located at a position which is lower than the main surface 13a of the semiconductor substrate 13. The gate electrode 22 may have, for example, a multilayered structure formed by stacking a titanium nitride film and a tungsten film in sequence.

In the semiconductor device of this embodiment, the thickness of the gate insulating film 21 and the work function of the gate electrode 22 may be adjusted so as to appropriately control the threshold voltages of the first and second transistors 19-1 and 19-2. It is preferable that saddle fin type cell transistors have the threshold voltage within the range between 0.5 V and 1.0 V. Here, when the threshold voltage is less than 0.5 V, the OFF leakage current is increased to deteriorate the information holding characteristics. On the other hand, when the threshold voltage is higher than 1.0 V, the current driving ability is lowered, writing of information is inadequate, and the information holding characteristics are deteriorated. Thus, the threshold voltage higher than 1.0 V is not preferable.

More specifically, when the thickness of the gate insulating film 21 is set in the range of 4 nm to 6 nm in terms of a silicon oxide film and the work function of the gate electrode 22 is set in the range of 4.6 eV to 4.8 eV, the threshold voltage of any one or both of the first and second transistors 19-1 and 19-2 may be 0.8 V to 1.0 V.

With reference to FIG. 2A and FIG. 2B, the buried insulating film 24 is arranged so as to cover the upper surface 22a of the gate electrode 22 and to embed the gate groove 18 having the gate insulating film 21 formed therein.

Further, an upper portion of the buried insulating film 24 protrudes from the main surface 13a of the semiconductor substrate 13, and an upper surface 24a of the protruding portion is flush with the upper surface 26a of the mask insulating film 26. As the buried insulating film 24, a silicon oxide film (SiO₂ film) may be used.

With reference to FIG. 2A and FIG. 2B, the mask insulating film 26 is provided on an upper surface 28a of the first diffusion region 28. The mask insulating film 26 has a groove-like opening 26A formed over the second isolation groove 54. The mask insulating film 26 functions as an etching mask when the second isolation groove 54 is formed in the semiconductor substrate 13 by anisotropic etching. As the mask insulating film 26, a silicon nitride film is used. In this case, the thickness of the mask insulating film 26 may be, for example, 50 nm.

With reference to FIG. 2A and FIG. 2B, the first diffusion region 28 is provided in a part of the semiconductor substrate 13 located on the first side surface 18a side so as to cover an upper portion 21A of the gate insulating film 21 formed on the first side surface 18a of the gate groove 18.

More specifically, the first side surface 18a of the gate groove 18 which forms the first transistor 19-1 and the first side surface 18a of the gate groove 18 which forms the second transistor 19-2 are opposed to side surfaces of the second isolation grooves 54, respectively, with the semiconductor substrate 13 disposed therebetween.

Therefore, the first diffusion region 28 is provided so as to include a part of a main surface 13a of the semiconductor substrate 13, the part being sandwiched between the first side surface 18a and the second isolation groove 54, and so as to cover the upper portion 21A of the gate insulating film 21 formed on the first side surface 18a.

A bottom surface 28b of the first diffusion region 28 is located at a position higher than the upper surface 22a of the gate electrode 22 which embeds the gate groove 18 (a position placed on the side of the main surface 13a of the semiconductor substrate 13). It is desirable that the distance between a horizontal line passing through the bottom surface 28b of the first diffusion region 28 and a horizontal line passing through the upper surface 22a of the buried gate electrode 22 be in the range of 5 nm to 10 nm. When the distance is less than 5 nm, the current driving ability is lowered the writing characteristics are deteriorated. On the other hand, when the distance is more than 10 nm, the junction field becomes large and the information holding characteristics are deteriorated.

The first diffusion region 28 is provided for each of the gate electrodes 22 forming the first and second transistors 19-1 and 19-2, respectively.

The first diffusion region 28 is a diffusion region which functions as a source/drain region (in the case of the structure illustrated in FIG. 2A and FIG. 2B, a source region) of the first and second transistors 19-1 and 19-2. When the semiconductor substrate 13 is a p-type silicon substrate, the first diffusion region 28 is formed by ion implantation of n-type impurities into the semiconductor substrate 13.

With reference to FIG. 2A and FIG. 2B, the second diffusion region 29 is provided in a part of the semiconductor substrate 13 which is arranged between the two gate grooves 18. More specifically, the second diffusion region 29 is provided so that it is shallower than the bottom portion 18c of each gate groove 18 and deeper than the top of the fin portion 15 (a part of the upper portion 15a which is the nearest to the main surface 13a of the semiconductor substrate 13), as readily understood from FIGS. 2A and 2B.

In other words, a bottom portion of the second diffusion region 29 is provided between the top of the upper portion 15a of the fin portion 15 and the bottom portion 18c of the gate groove 18. Specifically, a junction location between the second diffusion region 29 (for example, n-type diffusion region) and the semiconductor substrate 13 (for example, p-type channel) is arranged so that the lower limit of the depth of the junction location is placed at the location of the top of the fin portion 15 and the upper limit of the depth of the junction location is placed at the location of the bottom portion 18c of the gate groove 18. Thus, the second diffusion region 29 can cover all the gate insulating film 21 formed on the second side surfaces 18b of the two gate grooves 18 except for lower end portions of the gate insulating film 21.

Here, when the second diffusion region 29 is shallower than the top of the fin portion 15, it has been found out that the above-mentioned problem of the disturb failure would take place. On the other hand, when the second diffusion region 29 is deeper than the bottom portion 18c of the gate groove 18, the doped impurities (for example, n-type impurities) also reach the fin portion 15, and thus, the voltage becomes lower than a desired threshold voltage (Vt). When, in order to compensate for lowering the threshold voltage (Vt), the channel concentration (for example, concentration of p-type impurities) of the semiconductor substrate 13 becomes dense, the electric field intensity at a junction between the first diffusion region 28 (for example, n-type diffusion layer) and the semiconductor substrate 13 (for example, p-channel) becomes higher, and the information holding characteristics are deteriorated (see FIG. 23).

The second diffusion region 29 is a diffusion region which functions as a source/drain region (in the case of the structure illustrated in FIGS. 2, a drain region) common to the first and second transistors 19-1 and 19-2. When the semiconductor substrate 13 is of a p-type silicon, the second diffusion region 29 is formed by ion implantation of n-type impurities into the semiconductor substrate 13. In consequence, the fin portion 15 is of a p-type.

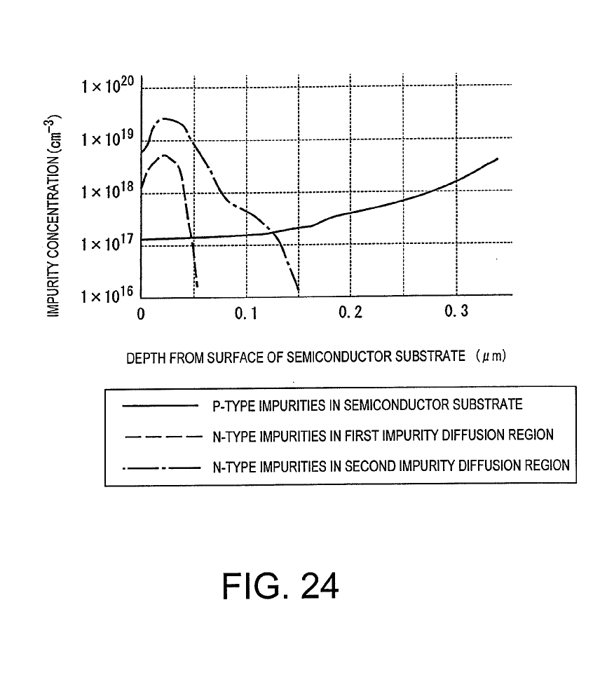

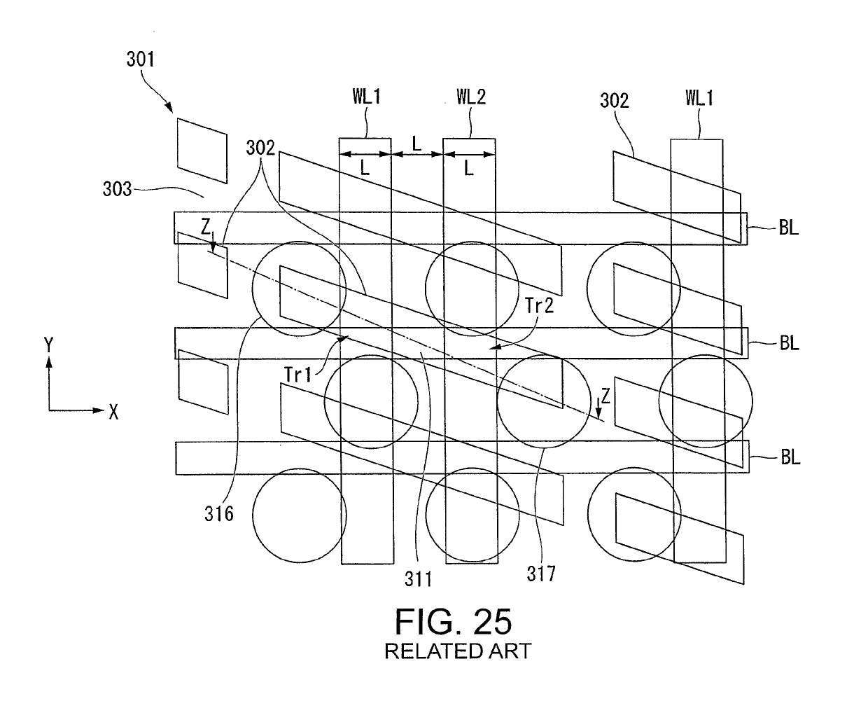

FIG. 24 is a graph showing the relationship of junction locations of respective diffusion regions of the semiconductor device 10 according to this embodiment. In FIG. 24, the abscissa represents the depth from the main surface 13a of the semiconductor substrate 13, while the ordinate represents the impurity concentrations of the semiconductor substrate 13 and the first and second diffusion regions 28 and 29, respectively. Further, in the figure, points of intersection of the profiles of the first and second diffusion regions 28 and 29 and the profile of the semiconductor substrate 13 are representative of metallurgical junction locations.

FIG. 24 illustrates the relationship among the depth of the gate groove 18, the height H of the fin portion 15, and the junction location of the second diffusion region 29.

In this way, the semiconductor device 10 of this embodiment includes the fin portion 15 provided at the bottom portion 18c of the gate groove 18, and further, the first diffusion region 28 including the part of the main surface 13a of the semiconductor substrate 13. The first diffusion region 28 is partially sandwiched between the first side surface 18a and the second isolation groove 54 and covers the upper portion 21A of the gate insulating film 21 arranged on the first side surface 18a. Furthermore, the second diffusion region 29 is arranged in the part of the semiconductor substrate 13 located between the two gate grooves 18 and covers all the gate insulating film 21 arranged on the second side surfaces 18b of the pair of gate grooves 18 except for lower end portions of the gate insulating film 21.

This structure makes it possible to suppress formation of any channel region in the part of the semiconductor substrate 13 which is located on an upper side of the bottom portion of the second diffusion region 29 and which is contacted with the second side surface 18b. This is because, when the first and second transistors 19-1 and 19-2 are operated, a first channel region is formed in the fin portion 15 while a second channel region is formed in the part of the semiconductor substrate 13 held in contact with the lower portion of the gate insulating film 21 arranged on the first side surface 18a, in the part of the semiconductor substrate 13 held in contact with the bottom portion 18c of the gate groove 18, and in the part of the semiconductor substrate 13 below the bottom portion of the second diffusion region 29 arranged on the second side surface 18b.

In other words, the fin portion 15 which is covered with the gate electrode 22 so that the gate electrode 22 straddles the fin portion via the gate insulating film 21 serves as channel regions together with the three surfaces forming the gate groove 18.

Specifically, when the first and second transistors 19-1 and 19-2 are put in the ON state, the fin portion 15 is completely depleted, and thus, the resistance may be lower and current may flow more easily, as compared with a case of a conventional transistor. This enables, even in a fine memory cell, to lower the channel resistance and to increase in the ON current.

Further, when one of the first and second transistors 19-1 and 19-2 is operated, the adverse effect of malfunction of the other transistor may be suppressed.

Therefore, even when the semiconductor device 10 is miniaturized in size and the gate electrodes 22 are arranged with narrow pitches, the first and second transistors 19-1 and 19-2 may be operated independently of each other with stability.

Further, the fin portions 15 are provided at the bottom portions 18c of the two gate grooves 18 which are adjacent to each other, and the height H of the fin portion 15 is not higher than 40 nm, as mentioned before. Herein, it is assumed that a state is formed in which “L” is held in a lower electrode 57 electrically connected to the first transistor 19-1 while “H” is held in another lower electrode 57 electrically connected to the second transistor 19-2. In the above-mentioned state, it is further assumed that ON/OFF of the gate electrode 22 (word line) corresponding to the first transistor 19-1 is repeated. In this event, since the fin portion 15 to be the channel region of the first transistor 19-1 is of a p-type, electrons e⁻ (not shown) are scarcely induced. Therefore, it is possible to suppress arrival of electrons e⁻ induced in the channel in the first transistor 19-1 to the second diffusion region 29 (drain region) forming the second transistor 19-2.

This prevents electrons e⁻ induced in the channel in the first transistor 19-1 from destroying “H” information held in the lower electrode 57 electrically connected to the second transistor 19-2 to change the state to the “L” state. As a result, a disturb failure in which the operation state of one of adjacent cells changes the state of information held in the other of the adjacent cells may be avoided.

Further, in a DRAM in which the distance between the two gate electrodes 22 which are arranged to be adjacent to each other is as short as 50 nm or less, also, the above-mentioned disturb failure may be suppressed.

Further, in the semiconductor device 10 of this embodiment, the carrier capture region 30 is provided below the gate insulating film 21 which is provided at the bottom portion of the gate groove 18 and on the surface of the active region 16 including the fin portion 15. This structure serves as an operation such that the carrier capture region 30 provided in or in proximity to the inversion layer may be a center of recombination and the electrons may disappear, when the gate electrode 22 changes abruptly from the ON state to the OFF state, even when electrons accumulated in the inversion layer formed at the gate interface are likely to be released in the semiconductor substrate 13. Therefore, the number of fault bits with respect to the number of disturbances may be reduced. In other words, the above-mentioned “disturb failure” in which the operation state of one of adjacent cells changes the state of information held in the other of the adjacent cells may be more effectively suppressed.

With reference to FIG. 2A and FIG. 2B, the opening 32 is formed between two buried insulating films 24 which protrude from the two gate grooves 18, respectively. The opening 32 is formed so as to expose an upper surface 29a of the second diffusion region 29.

With reference to FIG. 2A and FIG. 2B, the bit line contact plug 33 is provided so as to fill the opening 32, and is formed integrally with the bit line 34. A lower end of the bit line contact plug 33 is held in contact with the upper surface 29a of the second diffusion region 29. When the bit line 34 is formed of a multilayered film formed by staking a polysilicon film, a titanium nitride (TiN) film, and a tungsten (W) film in sequence, the bit line contact plug 33 may be formed of a polysilicon film.

With reference to FIG. 2A and FIG. 2B, the bit line 34 is formed on the upper surface 24a of the buried insulating film 24, and is formed integrally with the bit line contact plug 33. With this, the bit line 34 is electrically connected via the bit line contact plug 33 to the second diffusion region 29.

As the material of the bit line 34, a multilayered film formed by staking a polysilicon film, a titanium nitride film, and a tungsten film in sequence, a polysilicon film, a titanium nitride film, or the like may be used.

With reference to FIG. 2A and FIG. 2B, the cap insulating film 36 is provided so as to cover an upper surface of the bit line 34. The cap insulating film 36 not only protects the upper surface of the bit line 34 but also functions as an etching mask when a base material to be the bit line 34 is patterned by anisotropic etching (more specifically, dry etching). As the cap insulating film 36, a multilayered film formed by stacking a silicon nitride film (SiN film) and a silicon oxide film (SiO₂ film) in sequence may be used.

With reference to FIG. 2A and FIG. 2B, the sidewall film 37 is provided so as to cover side surfaces of the bit line 34. The sidewall film 37 has the function of protecting the side surfaces of the bit line 34. As the sidewall film 37, a multilayered film formed by stacking a silicon nitride film (SiN film) and a silicon oxide film (SiO₂ film) in sequence may be used.

With reference to FIG. 2A and FIG. 2B, the interlayer insulating film 38 is provided on the upper surface 26a of the mask insulating film 26 and on the upper surface 55a of the second isolation insulating film 55. An upper surface 38a of the interlayer insulating film is flush with an upper surface 36a of the cap insulating film 36. As the interlayer insulating film 38, for example, a silicon oxide film (SiO₂ film) formed by CVD or a solution-processed insulating film (silicon oxide film (SiO₂ film)) formed by SOG may be used.

With reference to FIG. 2A and FIG. 2B, the contact hole 41 is formed through the buried insulating film 24, the mask insulating film 26, and the interlayer insulating film 38 so as to expose a part of the upper surface 28a of the first diffusion region 28.

With reference to FIG. 2A and FIG. 2B, the capacitor contact plug 42 is provided so as to fill the contact hole 41. A lower end of the capacitor contact plug 42 is held in contact with a part of the upper surface 28a of the first diffusion region 28. With this, the capacitor contact plug 42 is electrically connected to the first diffusion region 28. An upper surface 42a of the capacitor contact plug 42 is flush with the upper surface 38a of the interlayer insulating film 38. The capacitor contact plug 42 may have, for example, a multilayered structure formed by stacking a titanium nitride film and a tungsten film in sequence.

With reference to FIG. 2A and FIG. 2B, the capacitor contact pad 44 is provided on the upper surface 38a of the interlayer insulating film 38 so that a part thereof is connected to the upper surface 42a of the capacitor contact plug 42. The lower electrode 57 forming the capacitor 48 on the capacitor contact pad 44 is connected to the capacitor contact pad 44. With this structure, the capacitor contact pad 44 serves to electrically connect the capacitor contact plug 42 and the lower electrode 57 to each other.

With reference to FIG. 1, the capacitor contact pads 44 are circular, and are arranged at staggered positions with respect to the capacitor contact plugs 42 in the Y direction. These capacitor contact pads 44 are arranged between adjacent bit lines 34 in the X direction.

More specifically, the capacitor contact pads 44 are arranged in a staggered pattern so that a center portion of one capacitor contact pad 44 is arranged over the gate electrode 22, a center portion of another capacitor contact pad 44 adjacent to the one capacitor contact pad 44 in the Y direction is arranged over a side surface of the gate electrode 22, and the above arrangement is repeated along the Y direction. In other words, the capacitor contact pads 44 are arranged in a zigzag pattern in the Y direction.

With reference to FIG. 2A and FIG. 2B, the silicon nitride film 46 is provided on the upper surface 38a of the interlayer insulating film 38 so as to surround an outer periphery of the capacitor contact pad 44.

One capacitor 48 is provided for one capacitor contact pad 44. One capacitor 48 includes one lower electrode 57, a capacitor insulating film 58 common to a plurality of lower electrodes 57, and an upper electrode 59 which is an electrode common to the plurality of lower electrodes 57.

The lower electrode 57 is provided on the capacitor contact pad 44 and is connected to the capacitor contact pad 44. The lower electrode 57 has a shape of a crown.

The capacitor insulating film 58 is provided so as to cover surfaces of the plurality of lower electrodes 57 which are not covered with the silicon nitride film 46 and are exposed, and so as to cover an upper surface of the silicon nitride film 46.

The upper electrode 59 is provided so as to cover a surface of the capacitor insulating film 58. The upper electrode 59 is arranged so as to fill the inside of the lower electrode 57 on which the capacitor insulating film 58 is formed and so as to fill a space between the plurality of lower electrodes 57. An upper surface 59a of the upper electrode 59 is arranged above upper ends of the plurality of lower electrodes 57.

The capacitor 48 having the above-mentioned structure is electrically connected via the capacitor contact pad 44 to the first diffusion region 28.

Note that, there may be further provided an interlayer insulating film (not shown) for covering the upper surface 59a of the upper electrode 59, a contact plug (not shown) provided in the interlayer insulating film, wiring (not shown) connected to the contact plug, and the like.

The semiconductor device 10 according to an embodiment of this invention is specified by the structure described below. The semiconductor device 10 includes: the semiconductor substrate 13; the plurality of first isolation regions 14, which are formed in the semiconductor substrate 13 so as to extend in the first direction, for defining the active region 16 having the plurality of element regions R; the plurality of second isolation regions 17, which are formed in the semiconductor substrate 13 so as to extend in the second direction intersecting the first direction, for partitioning the active region 16 into the plurality of element regions R; the pair of gate grooves 18, which are provided in a surface of the semiconductor substrate 13 and between adjacent second isolation regions 17 and 17 so as to extend in the second direction intersecting the first isolation regions and the active region, the pair of gate grooves each including the first and second side surfaces 18a and 18b opposed to each other and the bottom portion 18c; the fin portion 15, which is formed in a manner that a part of the active region 16 protrudes from the bottom portion 18c of the gate groove 18, the fin portion being formed by forming the gate groove 18 so that the first groove portion 18A thereof, which is formed in the active region 16, is shallower than the second groove portion 18B thereof, which is formed in the first isolation region 14, and so that a depth of a part of the first groove portion 18A, which is opposed to the second groove portion 12B, is substantially flush with a depth of the second groove portion 18B; the gate insulating film 21 for covering the gate grooves 18 and a surface of the fin portion 15; the pair of gate electrodes 22 each formed so as to straddle the fin portion 15 through intermediation of the gate insulating film 21, the pair of gate electrodes filling the lower portions of the pair of gate grooves 18, respectively; the two first diffusion regions 28 and 28 each provided in a main surface 13a of the semiconductor substrate 13 in a part between the second isolation region 17 and the gate groove 18, each of the two first diffusion regions 28 and 28 being connected to the capacitor 48; the one second diffusion region 29 provided in the semiconductor substrate 13 in a part between the pair of gate grooves 18 and 18 arranged so that the second side surfaces 18b and 18b thereof are opposed to each other, the one second diffusion region 29 being connected to the bit line 34; and the carrier capture region 30 which is provided below the gate insulating film 21 provided at the bottom portion of the gate groove 18 and on the surface of the active region 16 including the fin portion 15. The element region R includes: the first transistor 19-1 including at least one of the pair of gate electrodes 22, the fin portion 15, and one of the two first diffusion regions 28; and the second transistor 19-2 including at least the other of the pair of gate electrodes 22, the fin portion 15, and the other of the two first diffusion regions 28, the first transistor 19-1 and the second transistor 19-2 sharing the one second diffusion region 29. The depth of the bottom portion 18c of the gate groove 18 is 150 nm to 200 nm from the main surface 13a of the semiconductor substrate 13, and the height from the bottom portion 18c of the gate groove 18 to the top (upper portion) of the fin portion 15 is 10 nm to 40 nm.

Further, the second diffusion region 29 is provided so as to be shallower than the bottom portion 18c of the gate groove 18 and deeper than the top (upper portion) of the fin portion 15.

As described above, according to this embodiment, the semiconductor device 10 includes the fin portion 15 provided at the bottom portion 18c of the gate groove 18, and further, the first diffusion region 28 including the part of the main surface 13a of the semiconductor substrate 13, the part being sandwiched between the first side surface 18a and the second isolation groove 54, and covering the upper portion 21A of the gate insulating film 21 arranged on the first side surface 18a, and the second diffusion region 29 arranged in the part of the semiconductor substrate 13 located between the two gate grooves 18 and covering all the gate insulating film 21 arranged on the second side surfaces 18b of the pair of gate grooves 18 except for lower end portions of the gate insulating film 21. This enables a structure in which, when the first and second transistors 19-1 and 19-2 are operated, a first channel region is formed in the fin portion 15, a second channel region is formed in the part of the semiconductor substrate 13 held in contact with the lower portion of the gate insulating film 21 arranged on the first side surface 18a, in the part of the semiconductor substrate 13 held in contact with the bottom portion 18c of the gate groove 18, and in the part of the semiconductor substrate 13 below the bottom portion of the second diffusion region 29 arranged on the second side surface 18b, and no channel region is provided in the part of the semiconductor substrate 13 held in contact with the second side surface 18b and above the bottom portion of the second diffusion region 29.

In other words, the fin portion 15 which is covered with the gate electrode 22 so that the gate electrode 22 straddles the fin portion through intermediation of the gate insulating film 21 serves as the channel regions together with the three surfaces forming the gate groove 18.

In other words, when the first and second transistors 19-1 and 19-2 are in the ON state, the fin portion 15 is completely depleted, and thus, compared with a case of a conventional transistor, the resistance may be lower and current may flow more easily. This enables, even in a fine memory cell, to lower the channel resistance and to increase the ON current.

Further, when one of the first and second transistors 19-1 and 19-2 is operated, the adverse effect of malfunction of the other transistor may be suppressed.

Therefore, even when the semiconductor device 10 is miniaturized in size and the gate electrodes 22 are arranged with narrow pitches, the first and second transistors 19-1 and 19-2 may be operated independently of each other with stability.

Further, the fin portions 15 are provided at the bottom portions 18c of the two gate grooves 18 which are adjacent to each other, and the height H of the fin portion 15 is 40 nm or less. It is assumed that a state is formed in which “L” is held in the lower electrode 57 electrically connected to the first transistor 19-1 while “H” is held in the another lower electrode 57 electrically connected to the second transistor 19-2 and, with the state being maintained, ON/OFF of the gate electrode 22 (word line) corresponding to the first transistor 19-1 is repeated. In this event, the fin portion 15 to be the channel region of the first transistor 19-1 is a p-type fin portion, and thus, electrons e⁻ (not shown) are scarcely induced. Thus, this structure may suppress arrival of electrons e⁻ induced in the channel in the first transistor 19-1 at the second diffusion region 29 (drain region) forming the second transistor 19-2.

This prevents electrons e⁻ induced in the channel in the first transistor 19-1 from destroying “H” information held in the lower electrode 57 electrically connected to the second transistor 19-2 to change the state to the “L” state. In consequence, a disturb failure in which the operation state of one of adjacent cells changes the state of information held in the other of the adjacent cells may be suppressed.

Further, in a DRAM in which the distance between the two gate electrodes 22 which are arranged to be adjacent to each other is reduced in size to 50 nm or less, also, the above-mentioned disturb failure may be suppressed.

Further, the carrier capture region 30 is provided below the gate insulating film 21 which is provided at the bottom portion of the gate groove 18 and on the surface of the active region 16 including the fin portion 15. Therefore, when the gate electrode 22 which is opposed to the carrier capture region 30 via the gate insulating film 21 changes abruptly from the ON state to the OFF state, electrons accumulated in the inversion layer formed on the surface of the active region 16 to be the gate interface are likely to be released in the semiconductor substrate 13. In this event, the level in the carrier capture region 30 functions as a center of recombination, and thus, such electrons may disappear. Therefore, the above-mentioned disturb failure can be effectively suppressed.

Further, arrangement is made about the gate electrode 22 which fills the lower portion of the gate groove 18 via the gate insulating film 21 and the buried insulating film 24 which fills the gate groove 18 and which covers the upper surface 22a of the gate electrode 22. This structure serves not to protrude the gate electrode 22 upwards from the main surface 13a of the semiconductor substrate 13.

When a DRAM is structured as the semiconductor device 10 like in the above-mentioned embodiment, it is readily possible to manufacture the semiconductor device 10 because the bit line 34 and the capacitor 48 are easily formed after formation of the gate electrode 22.

### (Method of Manufacturing Semiconductor Device)

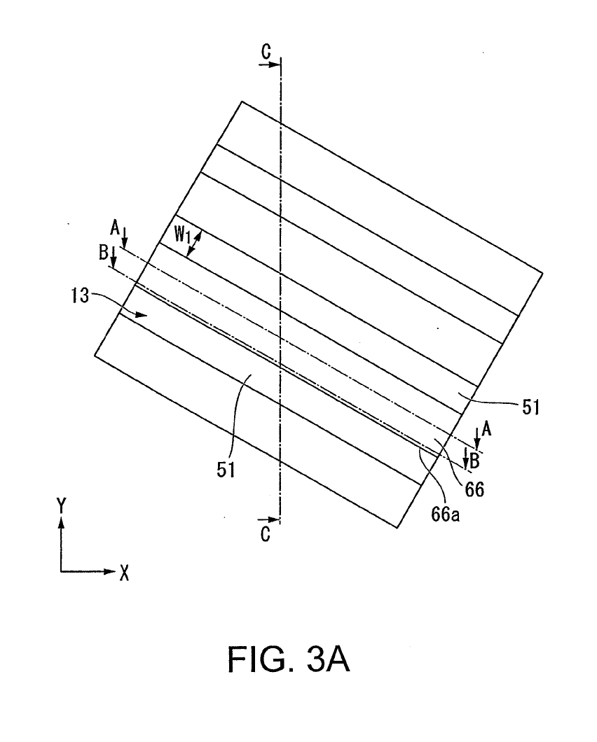

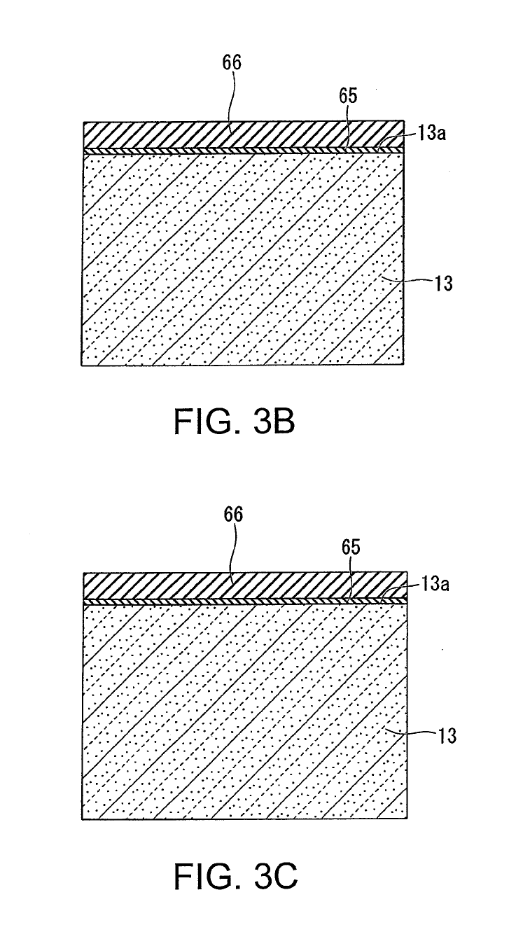

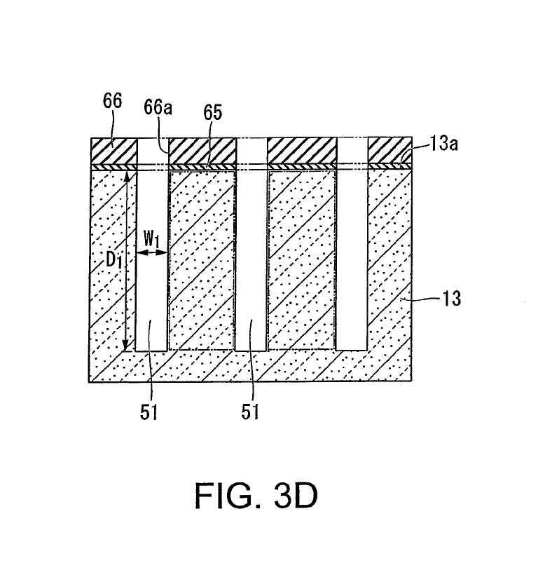

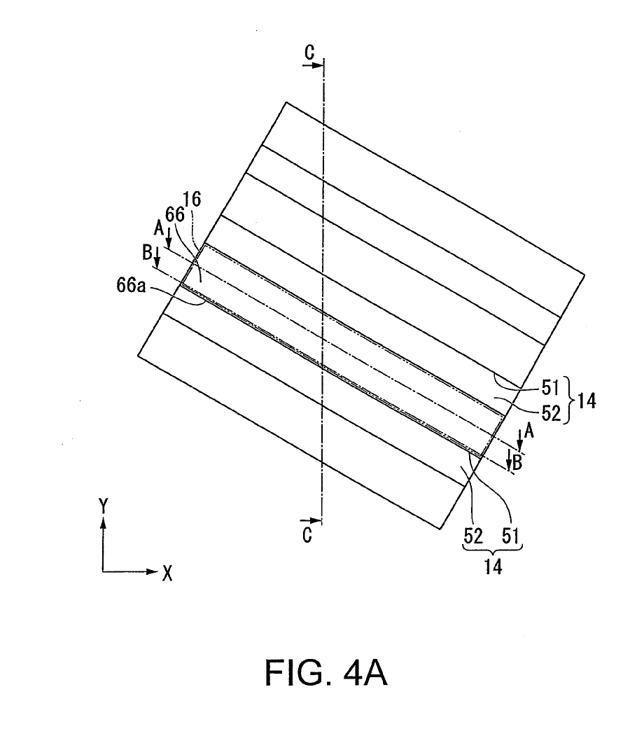

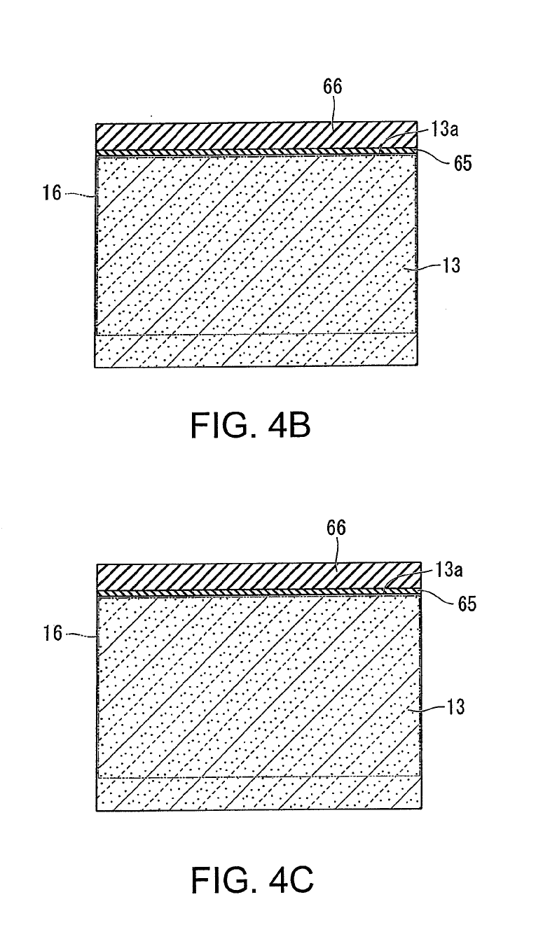

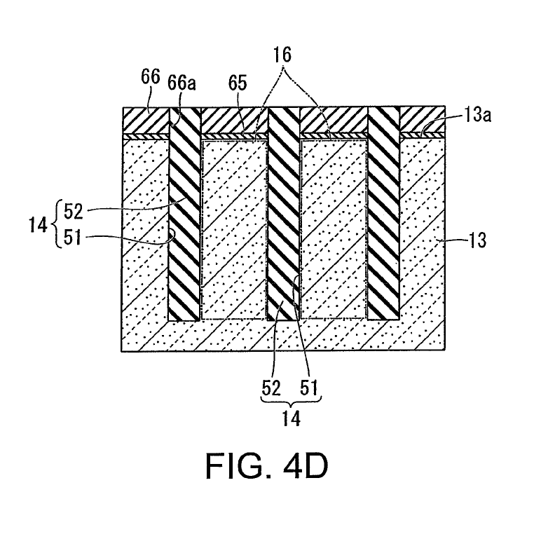

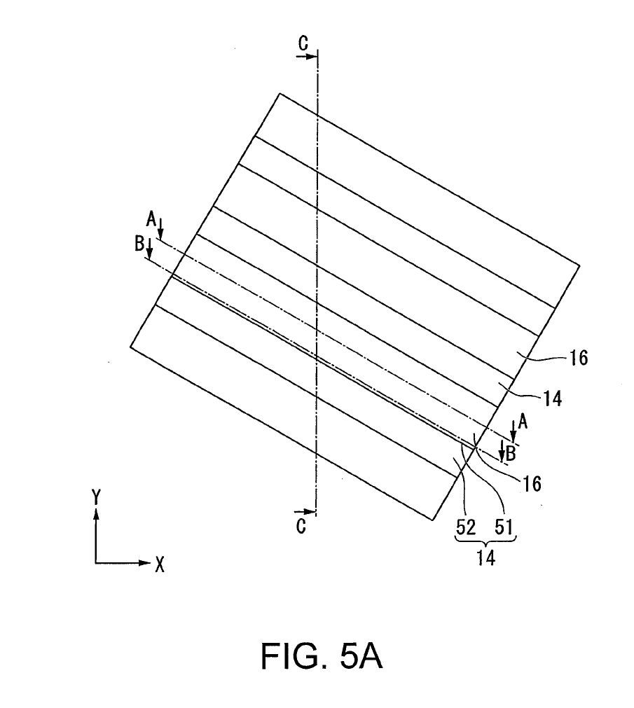

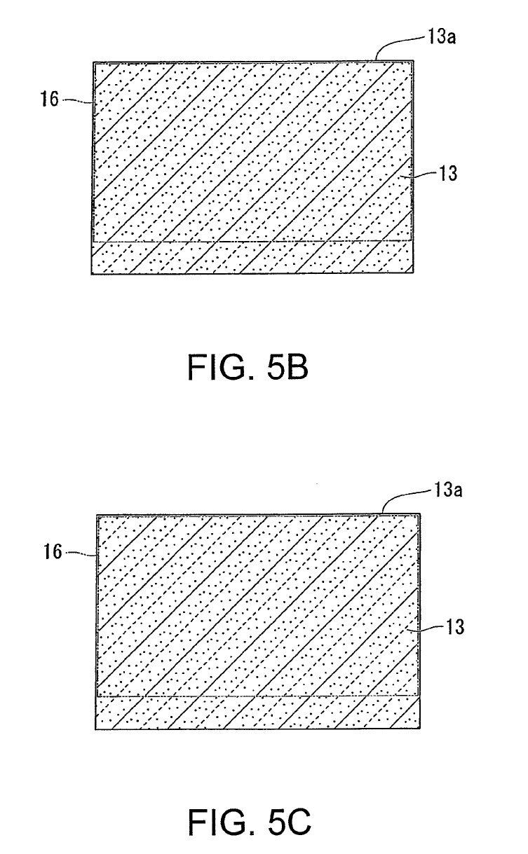

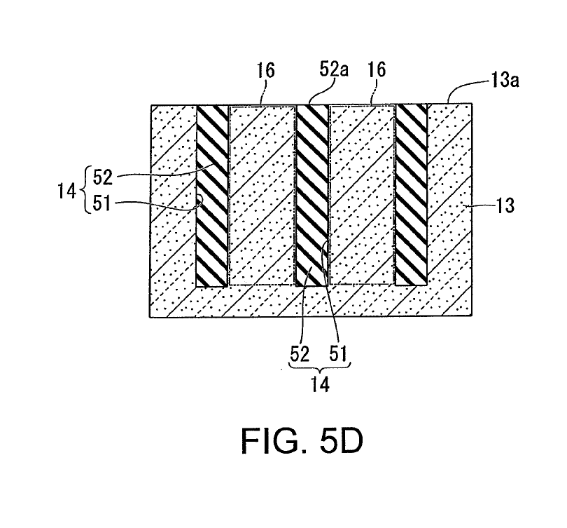

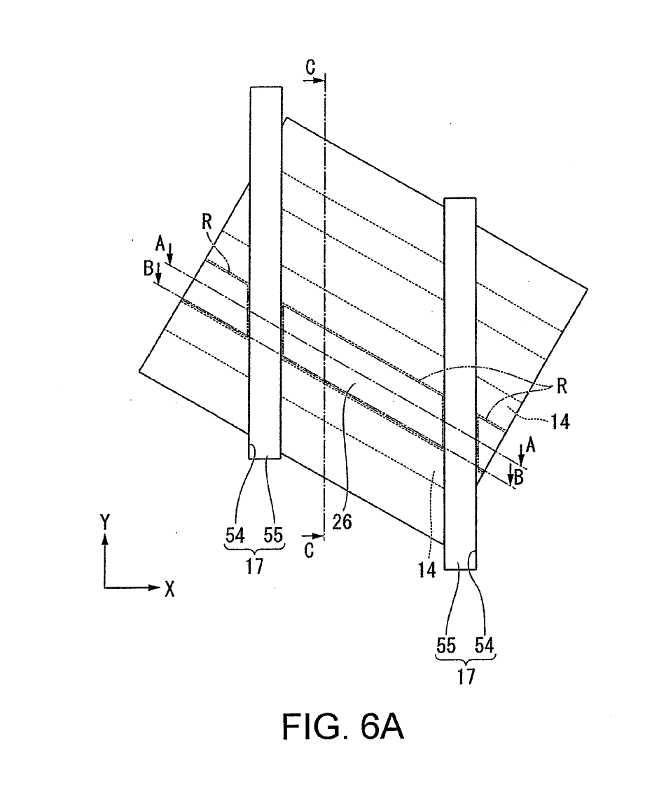

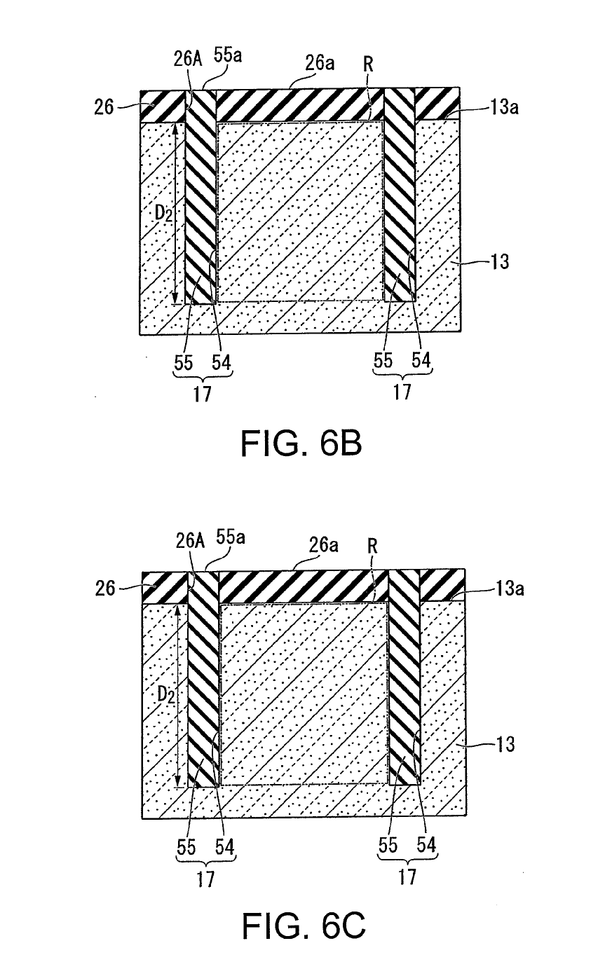

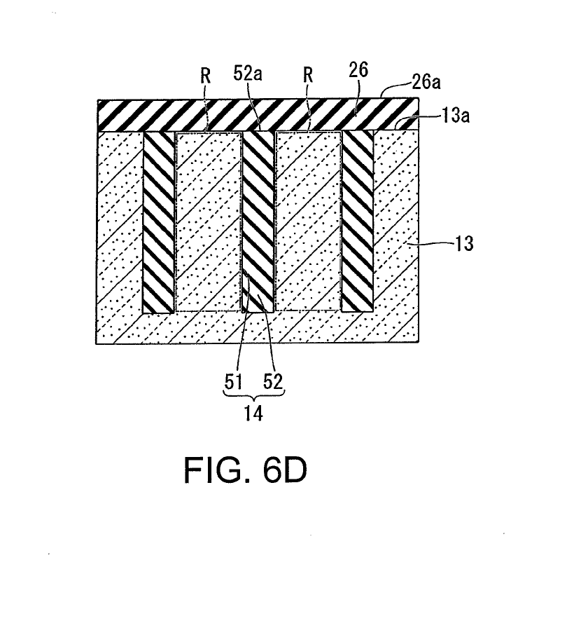

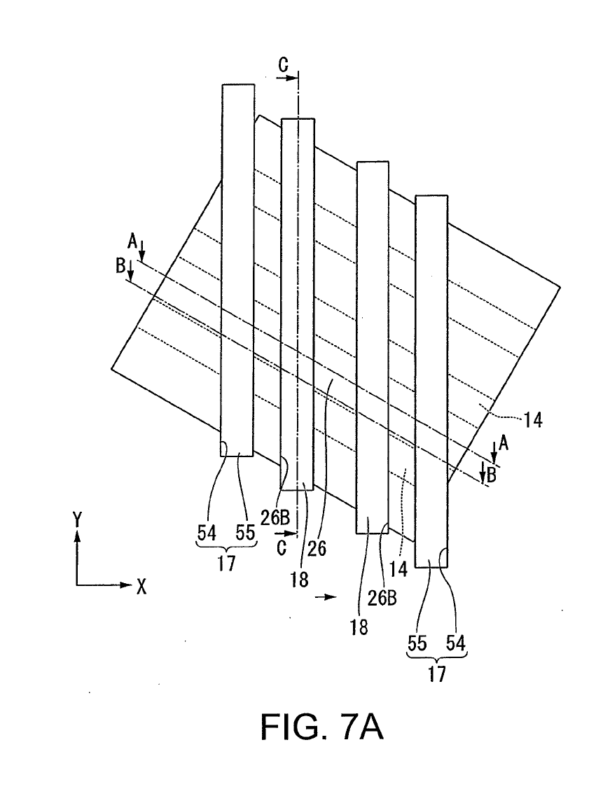

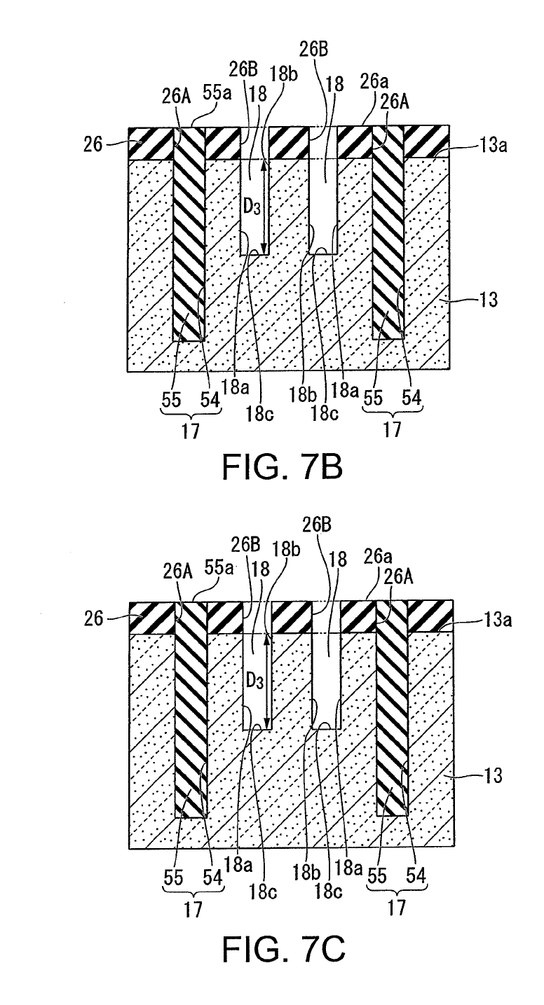

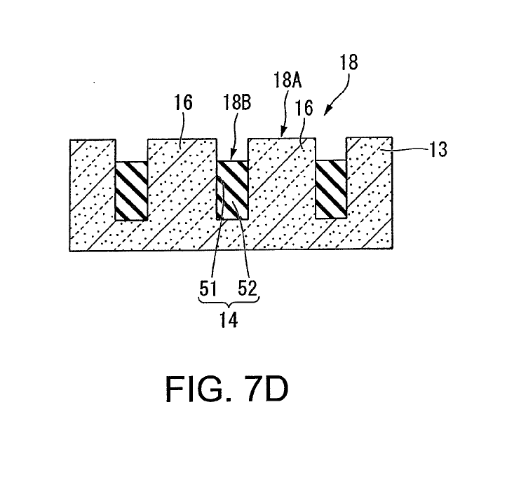

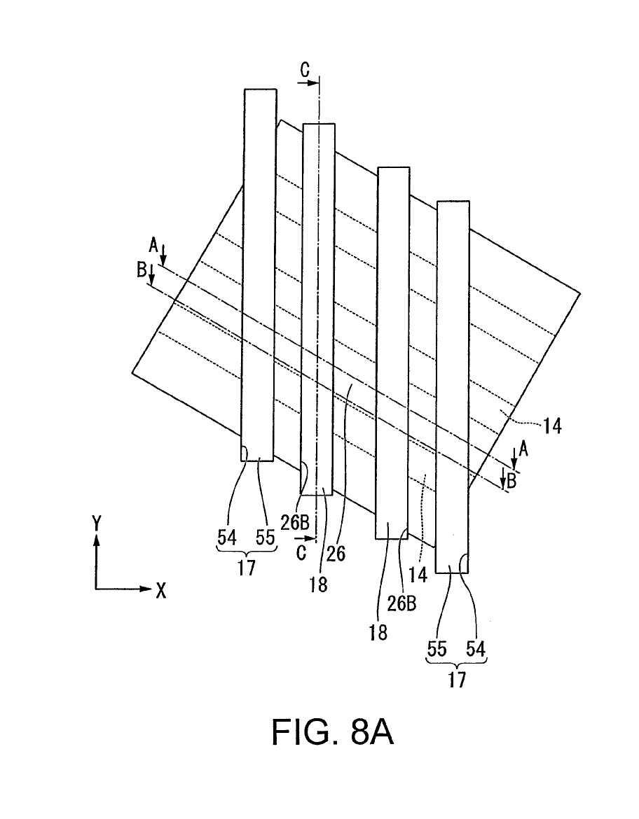

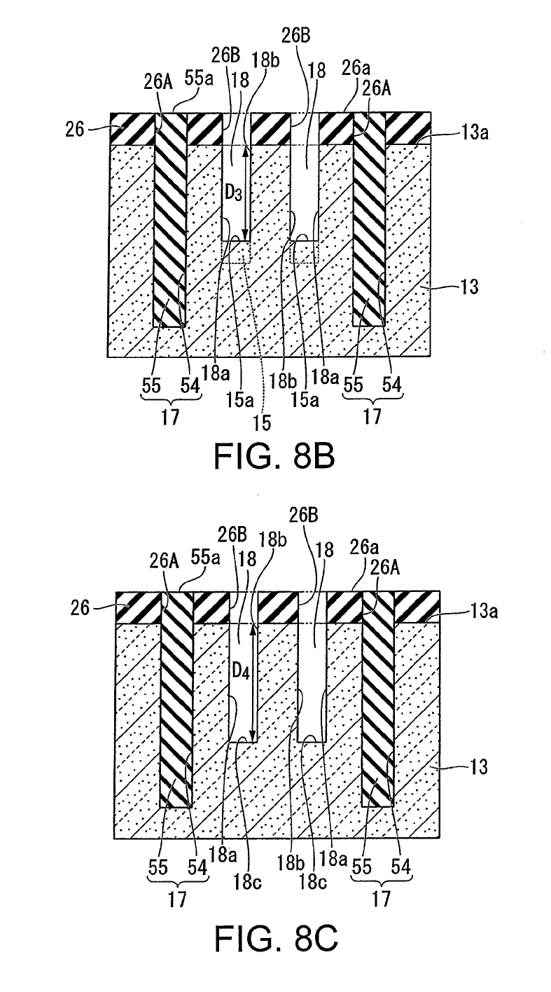

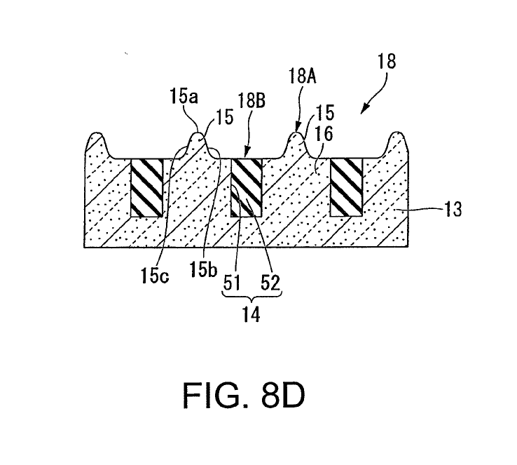

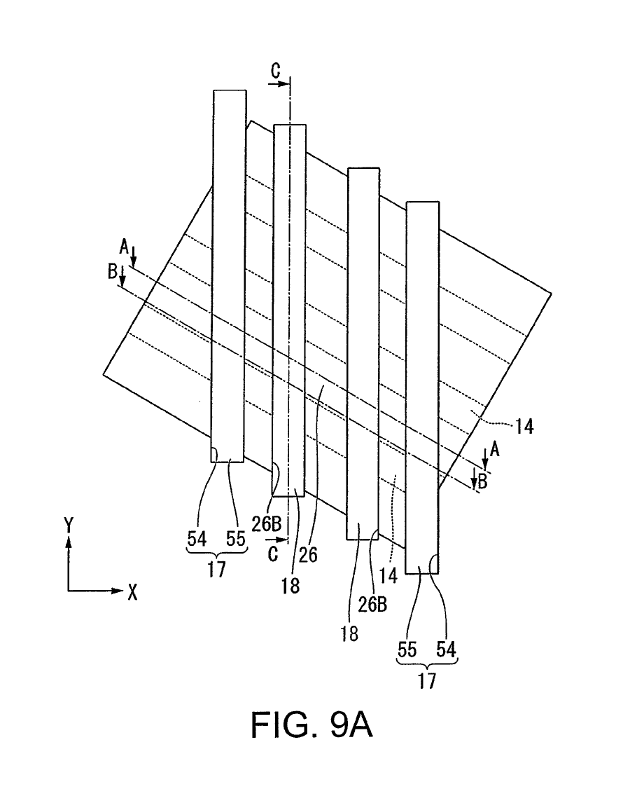

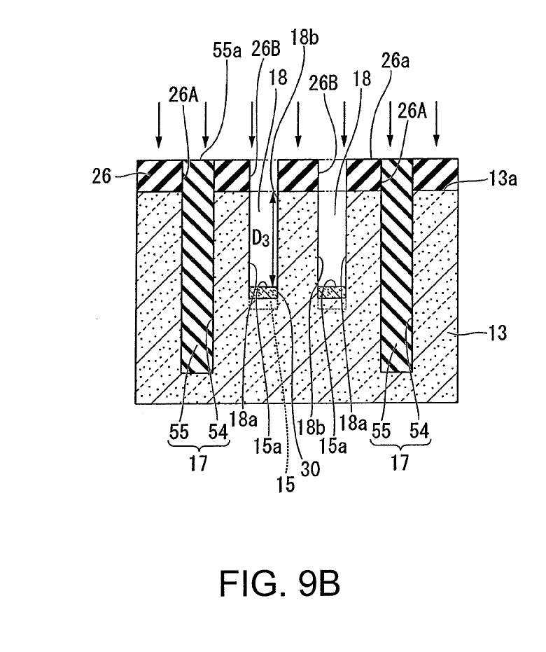

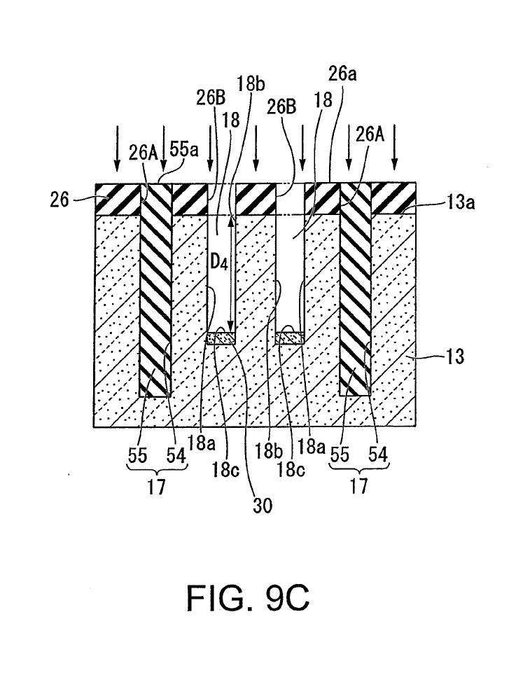

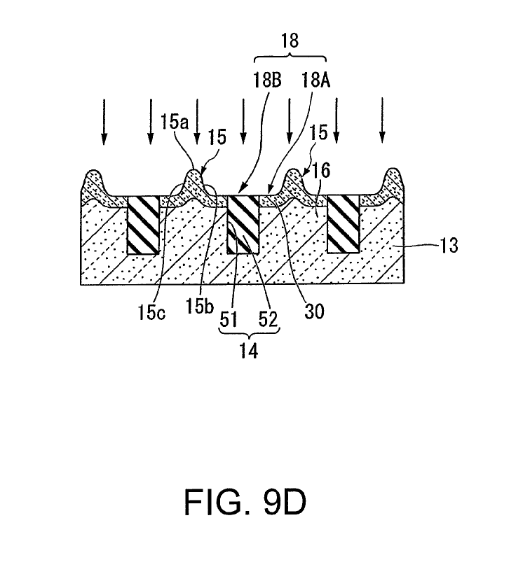

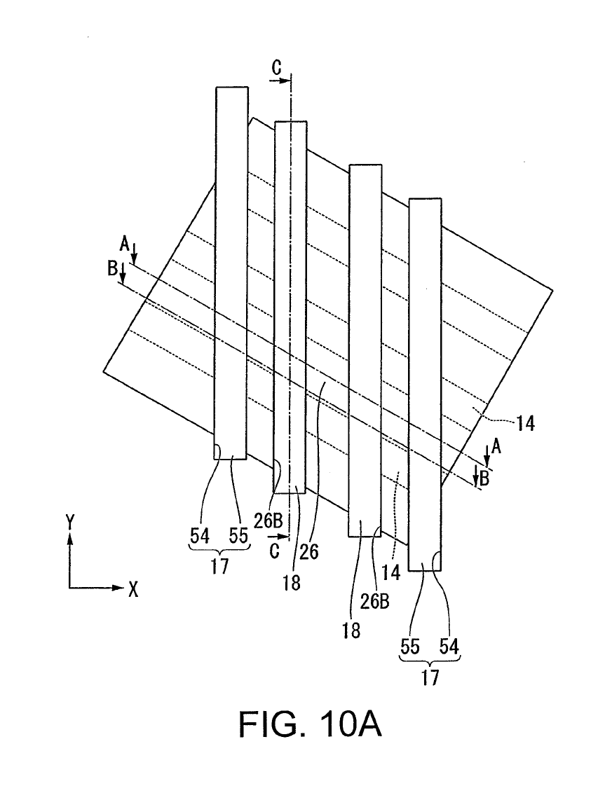

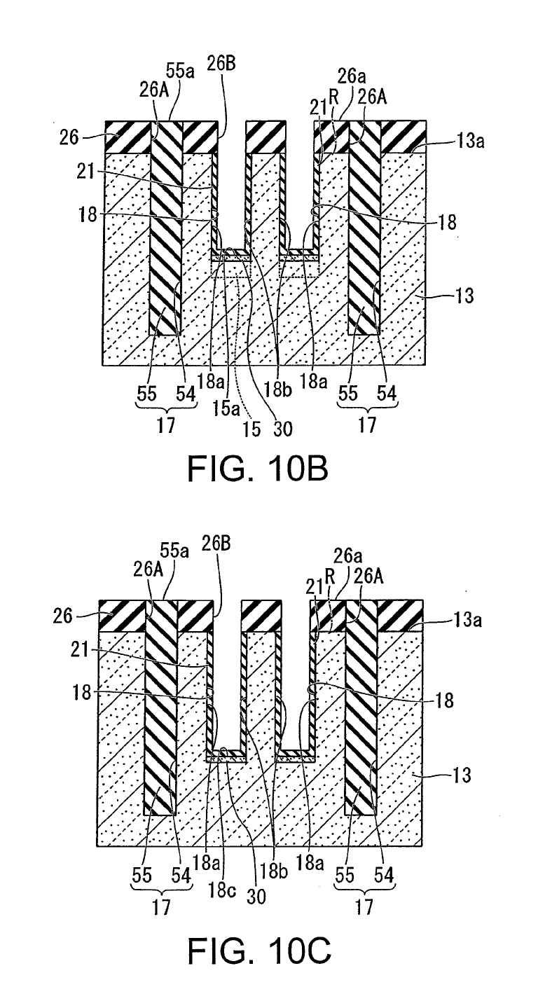

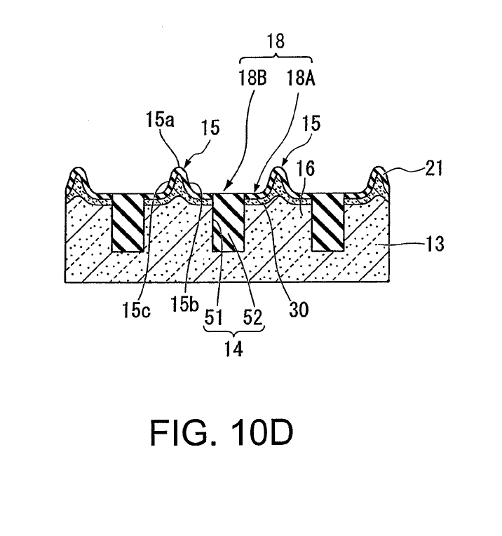

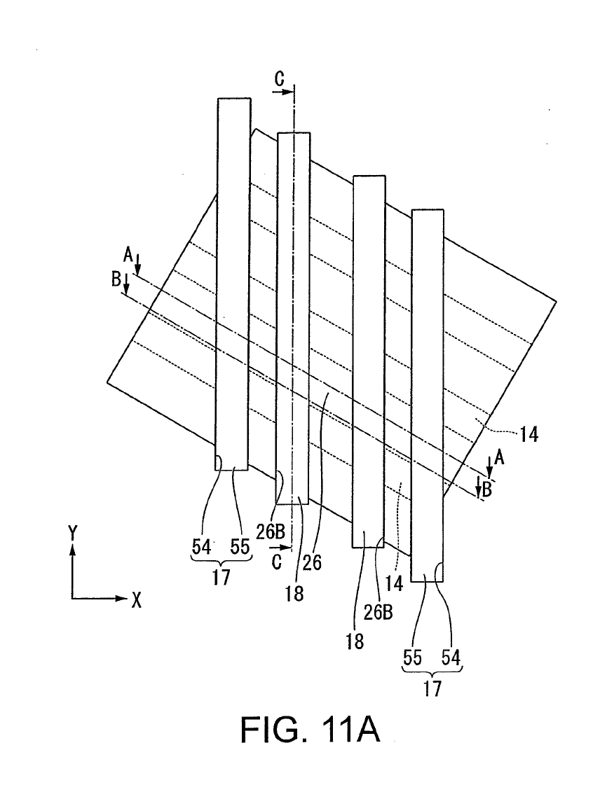

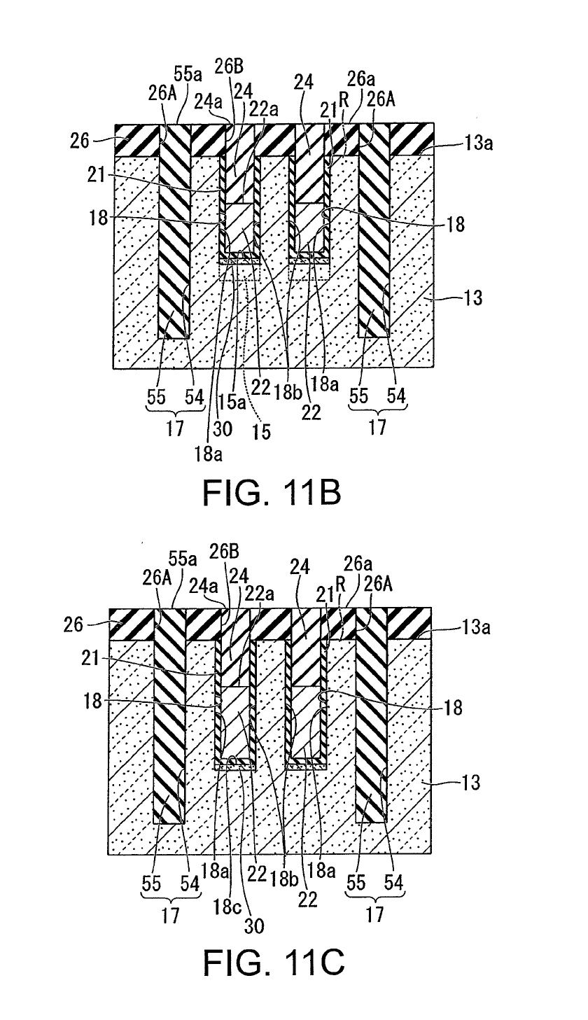

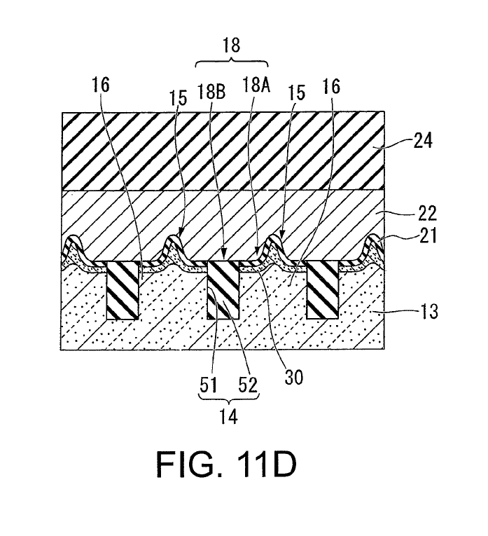

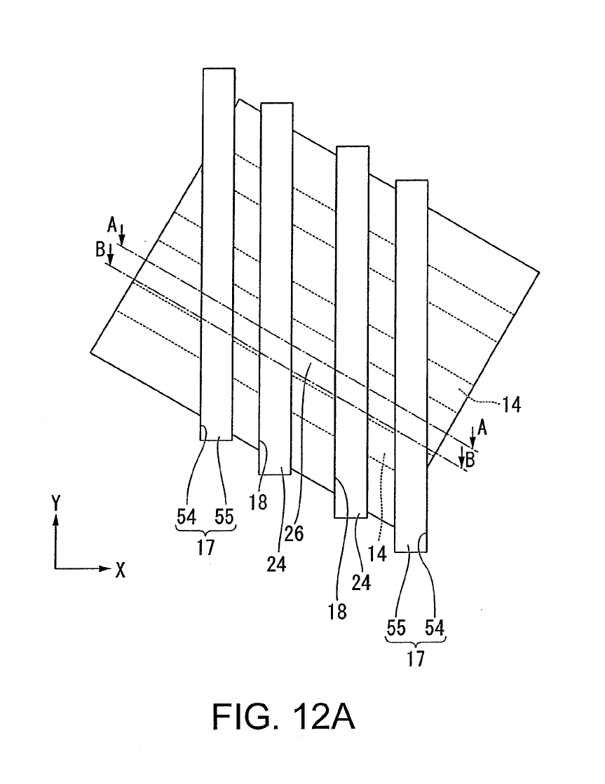

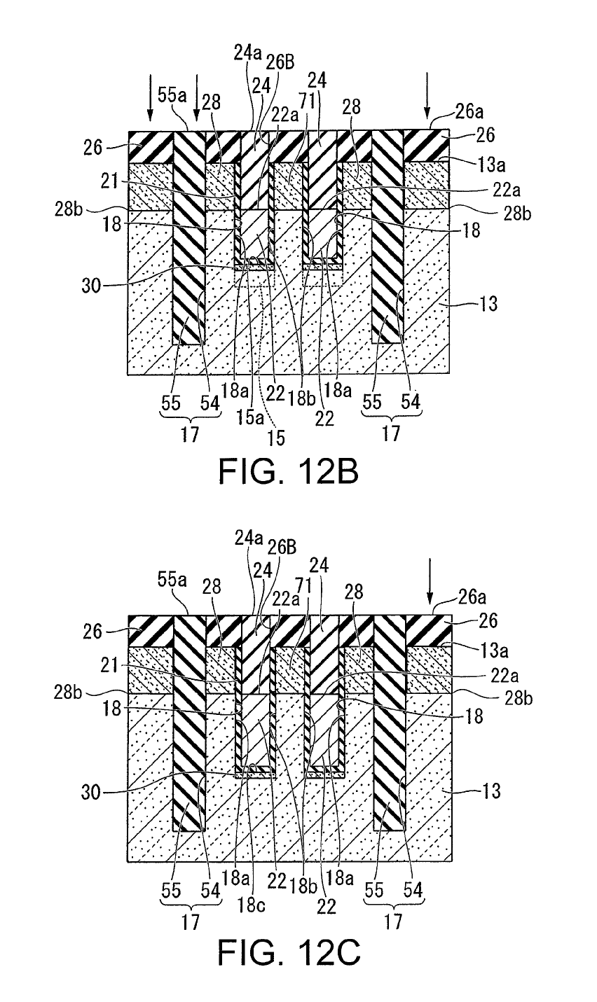

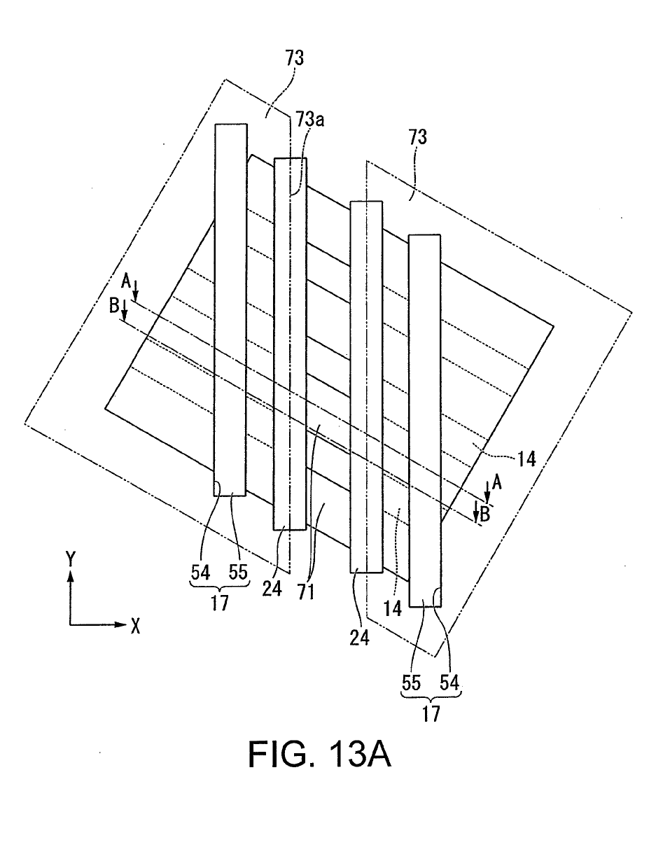

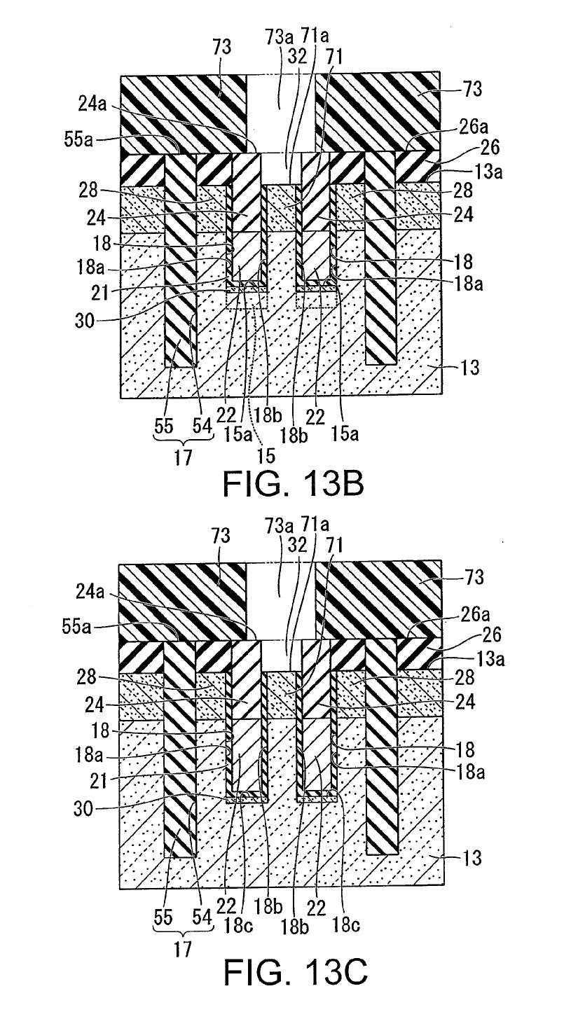

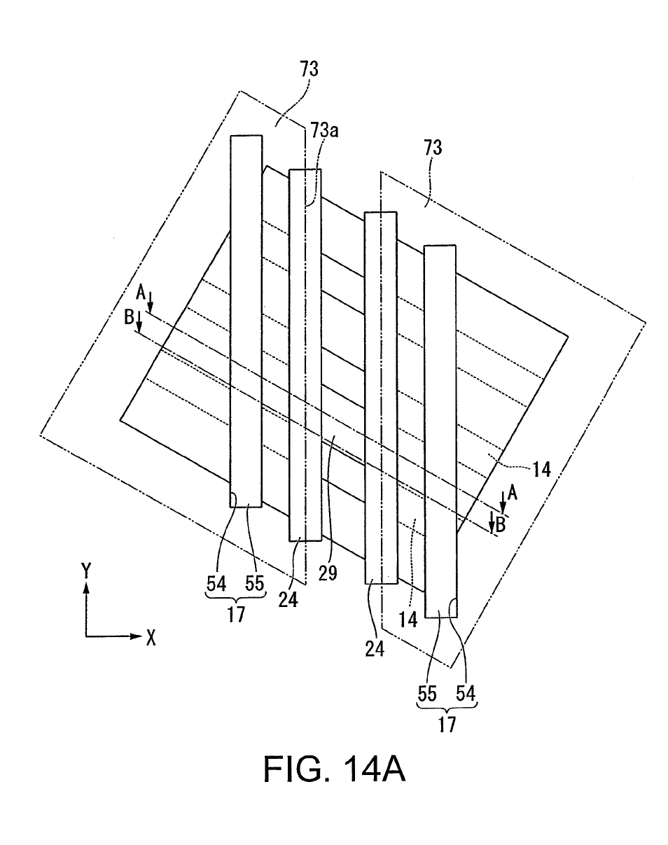

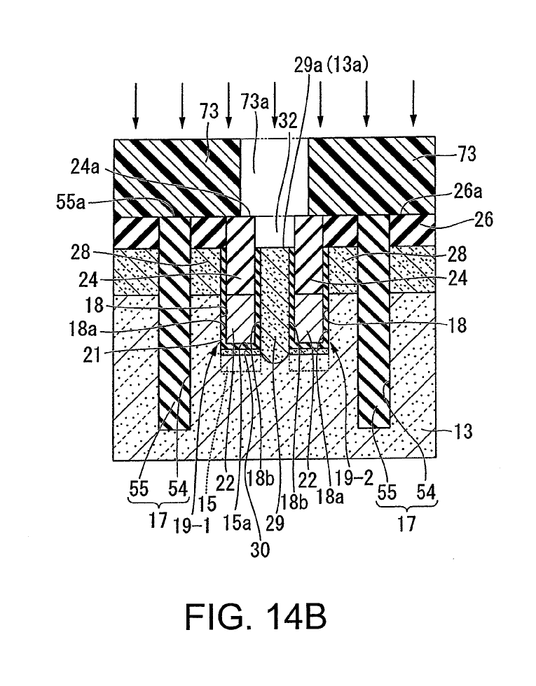

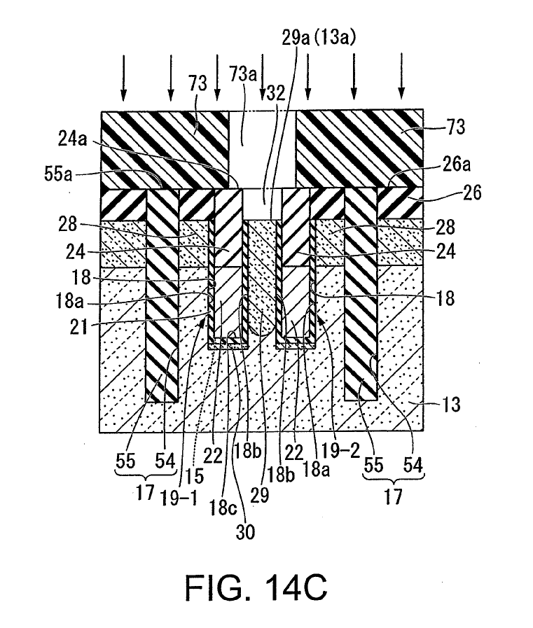

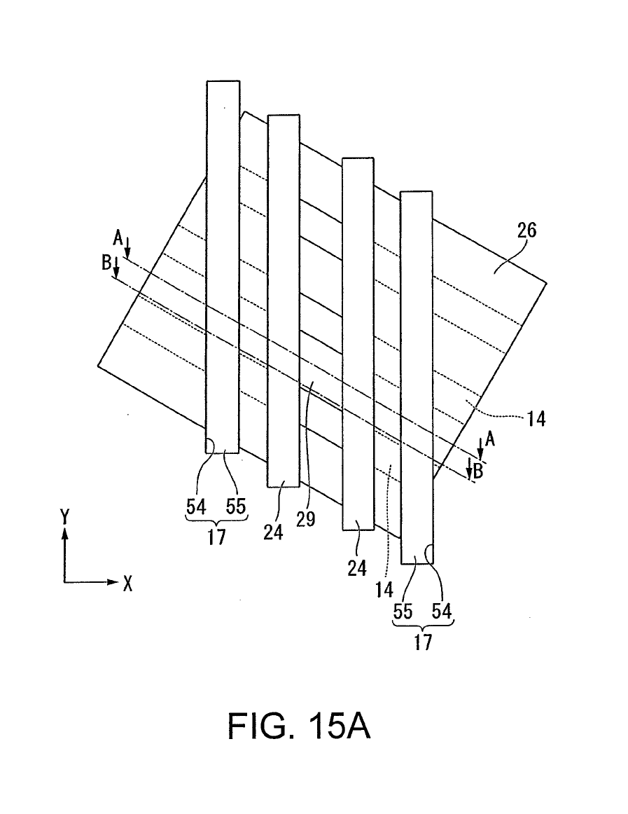

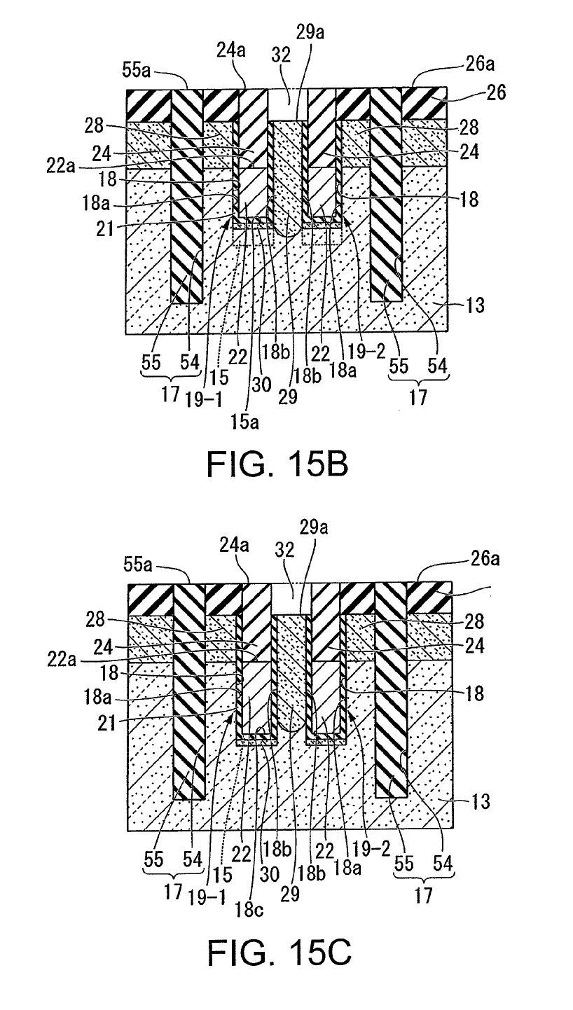

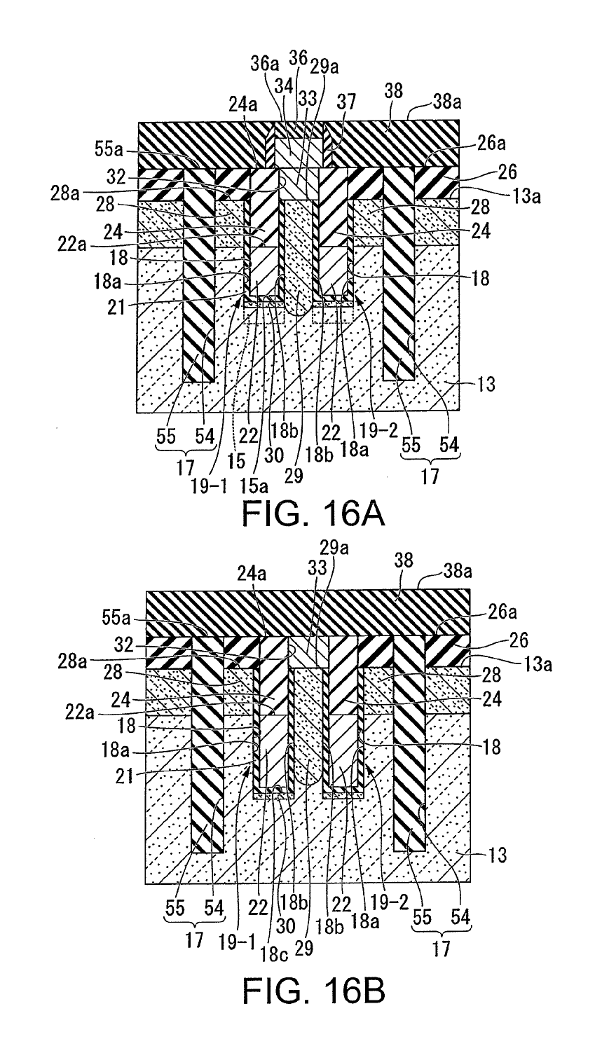

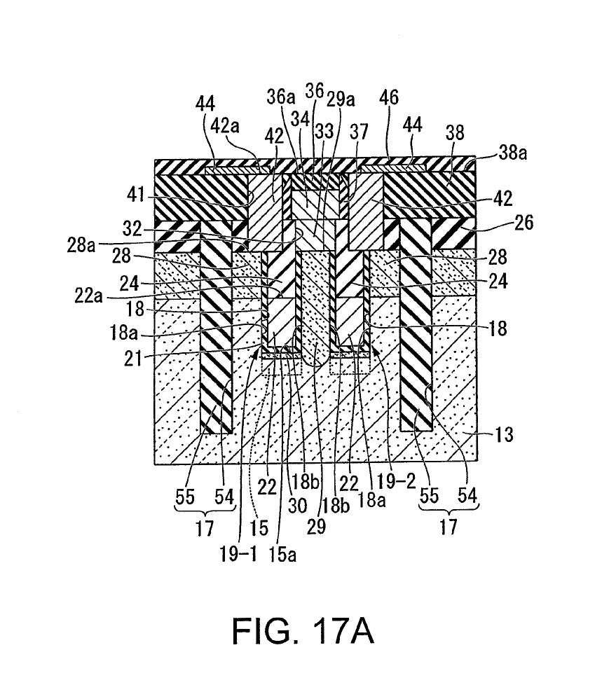

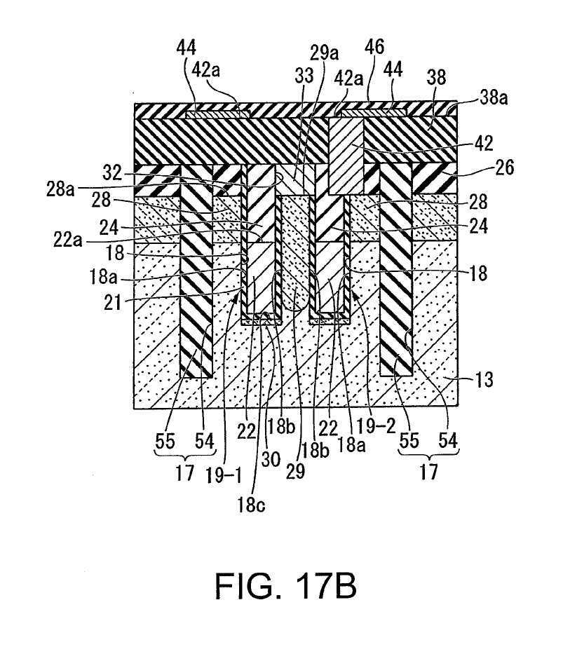

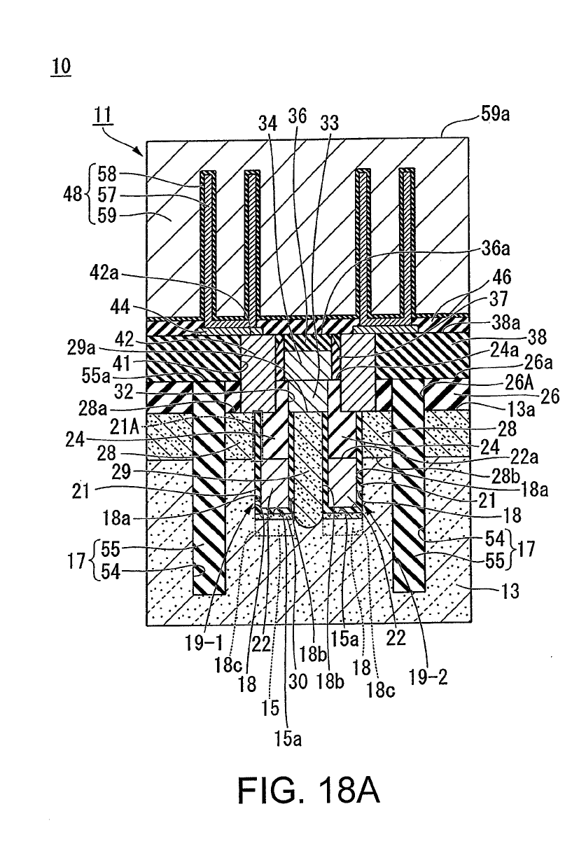

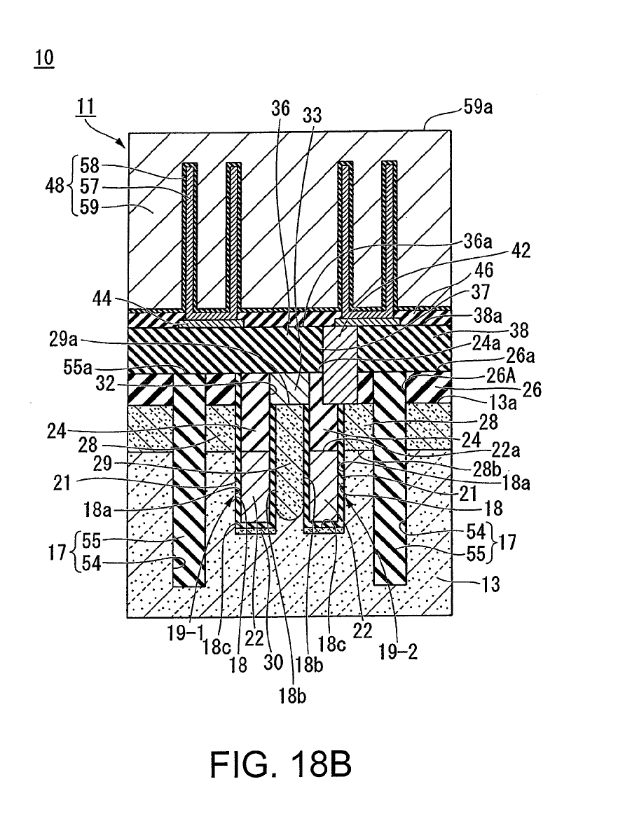

Description would be made about a method of manufacturing the semiconductor device 10 of this embodiment (more specifically, the memory cell array 11) with reference to FIG. 3A to FIG. 3D, FIG. 4A to FIG. 4D, FIG. 5A to FIG. 5D, FIG. 6A to FIG. 6D, FIG. 7A to FIG. 7D, FIG. 8A to FIG. 8D, FIG. 9A to FIG. 9D, FIG. 10A to FIG. 10D, FIG. 11A to FIG. 11D, FIG. 12A to FIG. 12C, FIG. 13A to FIG. 13C, FIG. 14A to FIG. 14C, FIG. 15A to FIG. 15C, FIG. 16A, FIG. 16B, FIG. 17A, FIG. 17B, FIG. 18A, and FIG. 18B.

Here, the line A-A of FIG. 3A to FIG. 15A corresponds to the line A-A of FIG. 1 while the line B-B of FIG. 3B to FIG. 15B corresponds to the line B-B of FIG. 1.

Further, FIG. 3D to FIG. 11D are sectional views taken along the line C-C of FIG. 3A to FIG. 11A, respectively. The cross sections taken along the line C-C are cross sections taken along the extending direction of the gate electrode 22 which is the buried word line in the semiconductor device 10 of this embodiment.

First, in a step illustrated in FIG. 3A to FIG. 3D, a pad oxide film 65 is formed on the main surface 13a of the semiconductor substrate 13. Then, a silicon nitride film 66 is formed on the pad oxide film 65 and has groove-like openings 66a (FIG. 3D) formed therein.

As illustrated in FIG. 3A and FIG. 3D, the plurality of openings 66a extend so as to be strip-like in the direction (first direction) which is tilted at the predetermined angle with respect to the X direction and are formed at predetermined intervals in the Y direction.

Here, the openings 66a are formed so as to expose portions of an upper surface of the pad oxide film 65 which correspond to regions in which the first isolation grooves 51 are to be formed. The openings 66a are formed by forming on the silicon nitride film 66 a patterned photoresist (not shown) and etching the silicon nitride film 66 by anisotropic etching with the photoresist being the mask. The photoresist is removed after the openings 66a are formed.

Then, by performing anisotropic etching (more specifically, dry etching) of the semiconductor substrate 13 by the use of the silicon nitride film 66 which has the openings 66a and which is operable as the mask, the first isolation grooves 51 which extend in the first direction are formed.

A width W₁ of the first isolation groove 51 may be, for example, 43 nm. Further, a depth D₁ of the first isolation groove 51 (depth relative to the main surface 13a of the semiconductor substrate 13) may be, for example, 250 nm.

Next, in a step illustrated in FIG. 4A to FIG. 4D, the first isolation insulating film 52 is embedded in the first isolation grooves 51.

More specifically, the first isolation grooves 51 are filled with a silicon oxide film (SiO₂ film) formed by a high density plasma method (HDP) or with a solution-processed silicon oxide film (SiO₂ film) formed by spin on glass (SOG).

Thereafter, a portion of the silicon oxide film (SiO₂ film) formed above an upper surface of the silicon nitride film 66 is removed by chemical mechanical polishing (CMP) to leave the first isolation insulating film 52 of a silicon oxide film (SiO₂ film) in the first isolation grooves 51, as shown in FIG. 4D.

In consequence, the first isolation region 14 is formed which includes the first isolation groove 51 and the first isolation insulating film 52 and which defines the strip-like active region 16 extending in the first direction.

Then, in a step illustrated in FIG. 5A to FIG. 5D, the silicon nitride film 66 illustrated in FIG. 4A to FIG. 4D is removed, and after that, the pad oxide film 65 is also removed. More specifically, the silicon nitride film 66 is removed by hot phosphoric acid, and after that, the pad oxide film 65 is removed by a hydrogen fluoride (HF)-based etchant. This serves to expose the strip-like active region 16.

Next, a part of the first isolation insulating film 52 which protrudes from the main surface 13a of the semiconductor substrate 13 is removed and, as a result, an upper surface 52a of the first isolation insulating film 52 becomes flush with the main surface 13a of the semiconductor substrate 13. The part of the first isolation insulating film 52 which protrudes from the main surface 13a of the semiconductor substrate 13 is removed by, for example, wet etching.

Then, in a step illustrated in FIG. 6A to FIG. 6D, the mask insulating film 26 having groove-like openings 26A formed therein is formed on the main surface 13a of the semiconductor substrate 13 and the upper surface 52a of the first isolation insulating film 52 illustrated in FIG. 5A to FIG. 5D.

More specifically, the mask insulating film 26 is formed by forming a silicon nitride film (base material of the mask insulating film 26) which covers the main surface 13a of the semiconductor substrate 13 and the upper surface 52a of the first isolation insulating film 52, and then, forming a patterned photoresist (not shown) on the silicon nitride film, and forming the openings 26A by anisotropic etching with the photoresist being the mask.

Here, the plurality of openings 26A extend in the Y direction (second direction) and are formed at predetermined intervals with respect to the X direction (see FIG. 6A). Further, the openings 26A are formed so as to expose parts of the main surface 13a of the semiconductor substrate 13, which correspond to regions in which the second isolation grooves 54 are to be formed. The photoresist (not shown) is removed after the openings 26A are formed.

Then, anisotropic etching (more specifically, dry etching) of the semiconductor substrate 13 is carried out by using the mask insulating film 26 having the openings 26A as the mask to obtain the second isolation grooves 54 which extend in the second direction.

A depth D₂ (depth relative to the main surface 13a of the semiconductor substrate 13) of each of the second isolation grooves 54 may be, for example, 250 nm.

Then, the second isolation insulating film 55 is embedded in the second isolation grooves 54. More specifically, the second isolation grooves 54 are filled with a silicon oxide film (SiO₂ film) formed by HDP or with a solution-processed silicon oxide film (SiO₂ film) formed by SOG.

Then, CMP is carried out to remove a part of the insulating film formed above the upper surface 26a of the mask insulating film 26 to form the second isolation insulating film 55 of silicon oxide (SiO₂) which has the upper surface 55a flush with the upper surface 26a of the mask insulating film 26 formed in the second isolation groove 54.

Thus, it is possible to form the second isolation region 17 which includes the second isolation groove 54 and the second isolation insulating film 55 and which partitions the strip-like active region 16 illustrated in FIG. 5A to FIG. 5D into the plurality of element regions R.

The above-mentioned method is thus performed by forming the first isolation region 14 which includes the first isolation groove 51 formed in the semiconductor substrate 13, by filling the first isolation insulating film 52 which is embedded in the first isolation groove 51 and which defines the strip-like active region 16, by then forming the second isolation region 17 which includes the second isolation groove 54 formed in the semiconductor substrate 13, and by embedding the second isolation insulating film 55 in the second isolation groove 54 to define the plurality of element regions R.

As compared with a case in which a dummy gate electrode (not shown) to which a negative potential is given is provided through the gate insulating film 21 in the second isolation groove 54 to define the plurality of element regions R, the above-mentioned method is advantageous in that the potential of the dummy gate electrode does not adversely affect the first and second transistors 19-1 and 19-2 (see FIG. 2), and thus, the first and second transistors 19-1 and 19-2 may be easily turned on and the data holding characteristics of the memory cell array 11 may be improved.

Then, in a step illustrated in FIG. 7A to FIG. 7D, two groove-like openings 26B which extend in the Y direction are formed in portions of the mask insulating film 26 which are located between two second isolation regions 17.

Here, the openings 26B are formed so as to expose parts of the main surface 13a of the semiconductor substrate 13, which correspond to forming regions of the gate grooves 18. The openings 26B are formed by forming on the mask insulating film 26 a patterned photoresist (not shown) and etching the mask insulating film 26 by anisotropic etching (more specifically, dry etching) by using the photoresist as the mask. The photoresist is removed after the openings 26B are formed.

Then, as illustrated in FIG. 7D, by anisotropic etching (more specifically, dry etching) with the mask insulating film 26 having the openings 26B formed therein being the mask, first, the first isolation insulating film 52 which forms the first isolation region 14 is selectively etched. This forms the second groove portion 18B of the gate groove 18 in the first isolation region 14. Here, a depth D₄ (depth relative to the main surface 13a of the semiconductor substrate 13, not shown) is shallower than the depths D₁ and D₂ of the first and second isolation grooves 51 and 54. More specifically, when the depths D₁ and D₂ of the first and second isolation grooves 51 and 54 are, for example, 250 nm, the depth D₄ may be in the range of 150 nm to 200 nm.

Then, the part of the semiconductor substrate 13, which forms the active region 16, is selectively etched. This process serves to form the first groove portion 18A of the gate groove 18 in the active region 16. Here, a depth D₃ (depth relative to the main surface 13a of the semiconductor substrate 13) of the first groove portion 18A is shallower than the depth D₄ of the second groove portion 18B. More specifically, the depth D₃ of the first groove portion 18A is shallower by 10 nm to 40 nm with respect to the depth D₄ of the second groove portion 18B. When the depths D₁ and D₂ of the first and second isolation grooves 51 and 54 are 250 nm, the depth D₄ of the gate groove 18 may be, for example, 150 nm.

Then, in a step illustrated in FIG. 8A to FIG. 8D, by isotropic etching (more specifically, dry/wet etching) with the mask insulating film 26 which has the openings 26B and which is operable as the mask, the first groove portion 18A which forms the gate groove 18 is selectively etched until the depth of the part of the first groove portion 18A opposed to the second groove portion 18B is substantially equal to the depth of the second groove portion 18B.

In this way, the depth of the end portion of the first groove portion 18A, which is formed in the active region 16, of the gate groove 18, the end portion being opposed to the second groove portion 18B, becomes substantially equal to the depth of the second groove portion 18B (that is, D₄) (see FIG. 8C and FIG. 8D). On the other hand, the depth of the center portion becomes equal to D₃ (see FIG. 8B and FIG. 8D). More specifically, the gate groove 18 having the first and second side surfaces 18a and 18b and the bottom portion 18c, and the fin portion 15 provided in a manner that a part of the active region 16 protrudes from the bottom portion 18c can be formed.

Then, in a step illustrated in FIG. 9A to FIG. 9D, a capture level-formable element is ion implanted in the bottom portion of the gate groove 18 to form the carrier capture region 30 at least in the surface of the active region 16 including the fin portion 15. Here, when, for example, carbon (C) is selected as the capture level-formable element, the ion implantation is carried out under conditions where the energy is 10 KeV and the dose is 5E13 atoms/cm². This forms the carrier capture region 30 having a width of 10 nm to 25 nm at a depth of 10 nm to 25 nm from the surface of the active region 16 including the fin portion 15.

It is preferable that the amount of the element to be implanted be, from the viewpoint of the reliability of the gate insulating film, such that change to an amorphous state is not caused. Further, it is preferable that the amount of the element to be implanted be to an extent that no serious defect such as transition is not caused to occur in the semiconductor substrate 13. More specifically, when carbon is selected as the element to be implanted, it is preferred that the ion implantation be carried out under conditions where the dose is 5E15 atoms/cm². Further, when fluorine is selected as the element to be implanted, it is, preferable that the ion implantation be carried out under conditions where the dose is 5E14 atoms/cm².

It is to be noted that, when, as in the manufacturing method of this embodiment, the carrier capture region 30 is formed before the gate insulating film 21 is formed, even if the amount of the element to be implanted is selected such that change to an amorphous state is not caused to occur as described above, accelerated oxidation or decelerated oxidation phenomenon is caused to occur at a stage of growing the gate insulating film to be described later. Thus, it is preferable that the gate oxidation conditions and the amount of dose are adjusted when the channel is formed.

Then, in a step illustrated in FIG. 10A to FIG. 10D, the gate insulating film 21 is formed which covers the surface of each gate groove 18 (that is, the first and second side surfaces 18a and 18b and the bottom portion 18c of the gate groove 18) and the surface of the fin portion 15 (that is, the upper portion 15a and the side surfaces 15b and 15c).

As the gate insulating film 21, for example, a single layer silicon oxide film (SiO₂ film), a film formed by nitriding a silicon oxide film (SiON film), a multilayered silicon oxide film (SiO₂ film), a multilayered film formed by stacking a silicon nitride film (SiN film) on a silicon oxide film (SiO₂ film), or the like may be used.

When the single layer silicon oxide film (SiO₂ film) is used as the gate insulating film 21, the gate insulating film 21 may be formed by thermal oxidation. In this case, the thickness of the gate insulating film 21 may be, for example, 6 nm.

Then, in a step illustrated in FIG. 11A to FIG. 11D, the gate electrode 22 is formed which fills the lower portion of the gate groove 18 so as to straddle the fin portions 15 through the gate insulating film 21 and so that the upper surface 22a thereof is lower than the main surface 13a of the semiconductor substrate 13 (see FIG. 11D).

More specifically, for example, by CVD, a titanium nitride film and a tungsten film are stacked in sequence so as to fill the gate groove 18, and then, the entire surface of the titanium nitride film and the tungsten film is etched back by dry etching so that the titanium nitride film and the tungsten film remain in the lower portion of the gate groove 18, thereby forming the gate electrode 22 including the titanium nitride film and the tungsten film. Each gate electrode 22 forms a word line of the memory cell.

Then, the buried insulating film 24 is formed which covers the upper surface 22a of the gate electrode 22 and fills the gate groove 18 and the groove-like opening 26B.

More specifically, an upper portion of the gate groove 18 and the opening 26B are filled with an insulating film (for example, silicon oxide film (SiO₂ film)) formed by HDP or with a solution-processed insulating film (for example, silicon oxide film (SiO₂ film)) formed by SOG.

Then, by CMP, a part of the insulating film, which is formed above the upper surface 26a of the mask insulating film 26, is removed. This forms the buried insulating film 24 which is an insulating film (for example, silicon oxide film (SiO₂ film)) filling the gate groove 18 and the opening 26B and which has the upper surface 24a flush with the upper surface 26a of the mask insulating film 26.

It is noted that, the saddle fin type gate electrode 22 which is a buried word line is formed in the steps illustrated in FIG. 3D to FIG. 11D, and thus, in the following figures, sectional views taken along the line C-C which correspond to FIG. 3A to FIG. 11A are omitted.

Then, in a step illustrated in FIG. 12A to FIG. 12C, through ion implantation of phosphorus (P) which is an n-type impurity (impurity having the conductivity type different from that of the p-type silicon substrate of the semiconductor substrate 13) in the entire upper surface of the structure illustrated in FIG. 11A to FIG. 11C under conditions where the energy is 100 KeV and the dose is 1E14 atoms/cm², the first diffusion region 28 is formed in a part of the semiconductor substrate 13 and is located between the gate groove 18 and the second isolation region 17. In addition, the first diffusion region 28 also forms a diffusion region 71 which acts as a part of the second diffusion region 29 and which is formed in a part of the semiconductor substrate 13 which is located between the two gate grooves 18.

This process serves to form, in the part of the semiconductor substrate 13, the first diffusion region 28 which is located on the side of the first side surface 18a of the gate groove 18 and which covers the upper portion 21A of the gate insulating film 21 formed on the first side surface 18a.

Here, the first diffusion region 28 is formed so that it includes the part of the main surface 13a of the semiconductor substrate 13 and it is sandwiched between the first side surface 18a and the second isolation groove 54. In addition, the first diffusion region 28 has the bottom surface 28b located at a position higher than the upper surface 22a of the buried gate electrode 22, although the bottom surface 28b is shown in the figures so that it is flush with the upper surface 22a of the buried gate electrode 22 for brevity of illustration.

It is noted that the thickness of the mask insulating film 26 at this stage may be, for example, 50 nm.

Then, in a step illustrated in FIG. 13A to FIG. 13C, a photoresist 73 having a groove-like opening 73a exposing a part of the upper surface 26a of the mask insulating film 26, which is located between the buried insulating films 24, is formed on the upper surface 24a of the buried insulating film 24, the upper surface 26a of the mask insulating film 26, and the upper surface 55a of the second isolation insulating film 55.

Then, the part of the mask insulating film 26, which is exposed from the opening 73a, is removed by etching (wet etching or dry etching) by using the photoresist 73 as the mask.

This step serves to expose an upper surface 71a of the diffusion region 71 and to expose a part of the upper surface 52a of the first isolation insulating film 52, which is flush with the upper surface 71a of the diffusion region 71.

Then, in a step illustrated in FIG. 14A to FIG. 14C, through selective ion implantation of phosphorus (P) which is an n-type impurity (impurity having the conductivity type different from that of the p-type silicon substrate of the semiconductor substrate 13) in the diffusion region 71 which is exposed from the photoresist 73 (in other words, in the part of the semiconductor substrate 13 in which the diffusion region 71 is formed), the second diffusion region 29 is formed in the part of the semiconductor substrate 13, which is located between the two gate grooves 18, so that the depth of the bottom portion thereof is between the top of the upper portion 15a of the fin portion 15 and the bottom portion 18c of the gate groove 18. The ion implantation is carried out by, after carrying out first stage ion implantation under conditions where the energy is 15 KeV and the dose is 5E14 atoms/cm², carrying out second stage ion implantation under conditions where the energy is 30 KeV and the dose is 2E13 atoms/cm² (two step implantation).

This step serves to form the second diffusion region 29 so as to cover the entire gate insulating film 21 provided on the second side surfaces 18b of the two gate grooves 18 except for lower end portions thereof, and forms the first and second transistors 19-1 and 19-2 each including the gate insulating film 21, the fin portion 15, the gate electrode 22, the buried insulating film 24, the first diffusion region 28, and the second diffusion region 29.

In this way, the semiconductor device 10 according to the first embodiment includes the fin portion 15 provided at the bottom portion 18c of the gate groove 18, and further, the first diffusion region 28 including the part of the main surface 13a of the semiconductor substrate 13, the part being sandwiched between the first side surface 18a and the second isolation groove 54, and covering the upper portion 21A of the gate insulating film 21 arranged on the first side surface 18a, and the second diffusion region 29 arranged in the part of the semiconductor substrate 13 located between the two gate grooves 18 and covering all the gate insulating film 21 arranged on the second side surfaces 18b of the pair of gate grooves 18 except for the lower end portions of the gate insulating film 21. This structure makes it possible that, when the first and second transistors 19-1 and 19-2 are operated, a first channel region is formed in the fin portion 15, a second channel region is formed in the part of the semiconductor substrate 13 held in contact with the lower portion of the gate insulating film 21 arranged on the first side surface 18a, in the part of the semiconductor substrate 13 held in contact with the bottom portion 18c of the gate groove 18, and in the part of the semiconductor substrate 13 below the bottom portion of the second diffusion region 29 arranged on the second side surface 18b. In other words, no channel region is provided in the part of the semiconductor substrate 13 held in contact with the second side surface 18b and above the bottom portion of the second diffusion region 29.

Specifically, when the first and second transistors 19-1 and 19-2 are in the ON state, the fin portion 15 is completely depleted, and thus, the resistance may be lower and current may flow more easily in comparison with the case of a conventional transistor. This structure is effective to lower the channel resistance and to increase the ON current, even in a fine memory cell.

Further, when one of the first and second transistors 19-1 and 19-2 is operated, the adverse effect of malfunction of the other transistor may be suppressed.

Therefore, even when the semiconductor device 10 becomes small in size and the gate electrodes 22 are arranged with tight pitches, the first and second transistors 19-1 and 19-2 may be operated independently of each other with stability.

Further, the fin portions 15 are provided at the bottom portions 18c of the two gate grooves 18 which are adjacent to each other and the height H of the fin portion 15 is 40 nm or less. It is assumed that, when a state is formed in which “L” is held in the lower electrode 57 electrically connected to the first transistor 19-1 while “H” is held in the another lower electrode 57 electrically connected to the second transistor 19-2 and when ON/OFF of the gate electrode 22 (word line) corresponding to the first transistor 19-1 is repeated, the fin portion 15 to be the channel region of the first transistor 19-1 is a p-type fin portion, and thus, electrons e⁻ (not shown) are rarely induced. Thus, this structure is very effective to suppress arrival of electrons e⁻ induced in the channel in the first transistor 19-1 at the second diffusion region 29 (drain region) forming the second transistor 19-2.

This prevents electrons e⁻ induced in the channel in the first transistor 19-1 from destroying “H” information held in the lower electrode 57 electrically connected to the second transistor 19-2 to change the state to the “L” state, and thus, a disturb failure in which the operation state of one of adjacent cells changes the state of information held in the other of the adjacent cells may be suppressed.

Further, in a DRAM in which the distance between the two gate electrodes 22 which are arranged to be adjacent to each other is caused to be 50 nm or less, also, the above-mentioned disturbance fault may be suppressed.

Then, in a step illustrated in FIG. 15A to FIG. 15C, the photoresist 73 illustrated in FIG. 14A to FIG. 14C is removed.

Then, in a step illustrated in FIG. 16A and FIG. 16B, the bit line contact plug 33 which fills the opening 32 and the bit line 34 arranged on the bit line contact plug 33 and extending in the X direction (see FIG. 1) are formed at a time.

More specifically, as illustrated in FIG. 16A, a polysilicon film, a titanium nitride film, and a tungsten film which are not shown are formed in sequence on the upper surface 24a of the buried insulating film 24 so as to fill the opening 32 (here, a film is formed so that the polysilicon film fills the opening 32).

Then, a silicon nitride film (SiN film) (not shown) which is to be a base material of the cap insulating film 36 is formed on a tungsten film (not shown also).

After that, by photolithography, a photoresist (not shown) which covers a region of the bit line 34 is formed on the silicon nitride film (SiN film).

Then, through patterning of the silicon nitride film (SiN film), the tungsten film, the titanium nitride film, and the polysilicon film by anisotropic etching (more specifically, dry etching) by using the photoresist as the mask, the cap insulating film 36 which is the silicon nitride film (SiN film), the bit line contact plug 33 which is the polysilicon film and which is held in contact with the upper surface 29a of the second diffusion region 29, and the bit line 34 which is arranged on the bit line contact plug 33 and which includes the polysilicon film, the titanium nitride film, and the tungsten film are formed at a time.

Then, through formation in sequence of a silicon nitride film (SiN film) and a silicon oxide film (SiO₂ film) which are not shown, so as to cover side surfaces of the bit line 34 and the cap insulating film 36, and, after that, etching back the entire surface of the silicon oxide film (SiO₂ film) and the silicon nitride film (SiN film), the sidewall film 37 which covers the side surfaces of the cap insulating film 36 and the side surfaces of the bit line 34 is formed.

Through formation of the sidewall film 37 by stacking the silicon nitride film (SiN film) and the silicon oxide film (SiO₂ film) in sequence in this way, when the solution-processed insulating film (more specifically, silicon oxide film (SiO₂ film)) is formed by SOG as the interlayer insulating film 38, the wettability of the silicon oxide film (solution-processed insulating film) is improved, and thus, voids in the silicon oxide film (solution-processed insulating film) may be suppressed.

Then, the interlayer insulating film 38 which covers the sidewall film 37 and has the upper surface 38a flush with the upper surface 36a of the cap insulating film 36 is formed on the upper surface 24a of the buried insulating film 24, the upper surface 26a of the mask insulating film 26, and the upper surface 55a of the second isolation insulating film 55. This step is for exposing the upper surface 36a of the cap insulating film 36 from the interlayer insulating film 38.

More specifically, through application of a solution-processed insulating film (silicon oxide film (SiO₂ film)) by SOG to the upper surface 24a of the buried insulating film 24, the upper surface 26a of the mask insulating film 26, and the upper surface 55a of the second isolation insulating film 55 so as to cover the sidewall film 37, and then carrying out of heat treatment, the silicon oxide film (solution-processed insulating film) is densified.

Further, when the silicon oxide film (solution-processed insulating film) is formed by SOG, an application liquid containing polysilazane is used. Further, it is preferable that the heat treatment be applied in a water vapor atmosphere.

Then, the silicon oxide film (solution-processed insulating film) which undergoes the heat treatment is polished by CMP until the upper surface 36a of the cap insulating film 36 is exposed. This serves to form the interlayer insulating film 38 having the upper surface 38a which is flush with the upper surface 36a of the cap insulating film 36.

Note that, although not shown in the structure illustrated in FIG. 14A and FIG. 14B, after the silicon oxide film (solution-processed insulating film) is polished, a silicon oxide film (SiO₂ film) which covers the upper surface 36a of the cap insulating film 36 and the upper surface 38a of the interlayer insulating film 38 may be formed by CVD.

Then, in a step illustrated in FIG. 17A and FIG. 17B, through carrying out anisotropic etching (more specifically, dry etching) of the interlayer insulating film 38, the mask insulating film 26, the buried insulating film 24, and the gate insulating film 21 by a self-aligned contact (SAC) method, the contact hole 41 which exposes a part of the upper surface 28a of the first diffusion region 28 is formed.

The dry etching here is carried out by divided steps including a step of selectively etching the silicon oxide film (SiO₂ film) and a step of selectively etching the silicon nitride film (SiN film).

Then, the capacitor contact plug 42 having the upper surface 42a, which is flush with the upper surface 38a of the interlayer insulating film 38, and the lower end, which is held in contact with the upper surface 28a of the first diffusion region 28, is formed in the contact hole 41.

More specifically, through stacking of a titanium nitride film (not shown) and a tungsten film (not shown) in sequence by CVD so as to fill the contact hole 41, and then, removal of, by polishing using CMP, unnecessary parts of the titanium nitride film and the tungsten film, which are formed on the upper surface 38a of the interlayer insulating film 38, the capacitor contact plug 42 which includes the titanium nitride film and the tungsten film is formed in the contact hole 41.

Then, the capacitor contact pad 44 which is held in contact with a part of the upper surface 42a of the capacitor contact plug 42 is formed on the upper surface 38a of the interlayer insulating film 38.

More specifically, a metal film (not shown) which is to be a base material of the capacitor contact pad 44 is formed so as to cover the upper surface 36a of the cap insulating film 36, the upper surface 42a of the capacitor contact plug 42, and the upper surface 38a of the interlayer insulating film 38.

Then, a photoresist (not shown) which covers a part of an upper surface of the metal film, which corresponds to a region in which the capacitor contact pad 44 is to be formed, is formed by photolithography. Then, through removal of an unnecessary part of the metal film exposed from the photoresist by dry etching with the photoresist used as the mask, the capacitor contact pad 44 which is the metal film is formed. The photoresist (not shown) is removed after the capacitor contact pad 44 is formed.

Then, the silicon nitride film 46 which covers the capacitor contact pad 44 is formed on the upper surface 36a of the cap insulating film 36, the upper surface 42a of the capacitor contact plug 42, and the upper surface 38a of the interlayer insulating film 38.

Then, in a step illustrated in FIG. 18A and FIG. 18B, a thick silicon oxide film (SiO₂ film) which is not shown is formed on the silicon nitride film 46. The thickness of the silicon oxide film (SiO₂ film) may be, for example, 1,500 nm.

Then, a patterned photoresist (not shown) is formed on the silicon oxide film (SiO₂ film) by photolithography. Then, through dry etching of the silicon oxide film (not shown) and the silicon nitride film 46 formed on the capacitor contact pad 44 by using the photoresist as the mask, a cylinder hole (not shown) which exposes the capacitor contact pad 44 is formed. After that, the photoresist (not shown) is removed.

Then, through formation of a conductive film (for example, titanium nitride film) on an inner surface of the cylinder hole (not shown) and on an upper surface of the capacitor contact pad 44, the lower electrode 57 which is the conductive film and which has a crown shape is formed.

Then, through removal of the silicon oxide film (not shown) by wet etching, the upper surface of the silicon nitride film 46 is exposed. Then, the capacitor insulating film 58 which covers the upper surface of the silicon nitride film 46 and the lower electrode 57 is formed.

Then, the upper electrode 59 is formed so as to cover the surface of the capacitive insulating film 58. Here, the upper electrode 59 is formed so that the upper surface 59a of the upper electrode 59 is arranged above the capacitor insulating film 58. In this way, the capacitor 48 including the lower electrode 57, the capacitive insulating film 58, and the upper electrode 59 is formed on each capacitor contact pad 44.

In this way, the semiconductor device 10 according to the first embodiment is manufactured. Note that, in reality, interlayer insulating films, via holes, wirings, and the like, which are not shown, are formed on the upper surface 59a of the upper electrode 59.

As described above, the method of manufacturing the semiconductor device of this embodiment includes forming the fin portion 15 at the bottom portion 18c of the gate groove 18, and further, forming the first diffusion region 28, which includes the part of the main surface 13a of the semiconductor substrate 13, the part being sandwiched between the first side surface 18a and the second isolation groove 54, and covers the upper portion 21A of the gate insulating film 21 arranged on the first side surface 18a, and the second diffusion region 29, which is arranged in the part of the semiconductor substrate 13 located between the two gate grooves 18 and covers all the gate insulating film 21 arranged on the second side surfaces 18b of the pair of gate grooves 18 except for lower end portions of the gate insulating film 21. This enables a structure in which, when the first and second transistors 19-1 and 19-2 are operated, a first channel region is formed in the fin portion 15, a second channel region is formed in the part of the semiconductor substrate 13 held in contact with the lower portion of the gate insulating film 21 arranged on the first side surface 18a, in the part of the semiconductor substrate 13 held in contact with the bottom portion 18c of the gate groove 18, and in the part of the semiconductor substrate 13 below the bottom portion of the second diffusion region 29 arranged on the second side surface 18b, and no channel region is provided in the part of the semiconductor substrate 13 held in contact with the second side surface 18b and above the bottom portion of the second diffusion region 29.

In other words, when the first and second transistors 19-1 and 19-2 are in the ON state, the fin portion 15 is completely depleted, and thus, in comparison with the case of a conventional transistor, the resistance may be lower and current may flow more easily. This enables, even in a fine memory cell, lowering of the channel resistance and increase in the ON current.

Further, when one of the first and second transistors 19-1 and 19-2 is operated, the adverse effect of misoperation of the other transistor may be suppressed.

Therefore, even when the semiconductor device 10 is caused to be small and the gate electrodes 22 are arranged with tight pitches, the first and second transistors 19-1 and 19-2 may be operated independently of each other with stability.

Further, the fin portions 15 are provided at the bottom portions 18c of the two gate grooves 18 which are arranged so as to be adjacent to each other, and the height H of the fin portion 15 is caused to be 40 nm or less, and thus, a state is formed in which “L” is held in the lower electrode 57 electrically connected to the first transistor 19-1 while “H” is held in the another lower electrode 57 electrically connected to the second transistor 19-2. When, with the state being maintained, ON/OFF of the gate electrode 22 (word line) corresponding to the first transistor 19-1 is repeated, the fin portion 15 to be the channel region of the first transistor 19-1 is a p-type fin portion, and thus, electrons e⁻ (not shown) are less liable to be induced, which may suppress arrival of electrons e⁻ induced in the channel in the first transistor 19-1 at the second diffusion region 29 (drain region) forming the second transistor 19-2.

This prevents electrons e⁻ induced in the channel in the first transistor 19-1 from destroying or corrupting “H” information held in the lower electrode 57 electrically connected to the second transistor 19-2 to change the state to the “L” state, and thus, a disturb failure in which the operation state of one of adjacent cells changes the state of information held in the other of the adjacent cells may be suppressed.

Further, in a DRAM in which the distance between the two gate electrodes 22 which are arranged to be adjacent to each other is caused to be 50 nm or less, also, the above-mentioned disturbance fault may be suppressed.

Further, according to the method of manufacturing the semiconductor device 10 of this embodiment, through ion implanting of a capture level-formable element in the bottom portion of the gate groove 18 and on the surface of the active region 16 including the fin portion 15 after the fin portion 15 is formed at the bottom portion of the gate groove 18 and before the gate insulating film 21 is formed, the carrier capture region 30 may be formed in proximity to a surface layer of the fin portion 15. This structure can suppress the above-mentioned disturb failure more effectively.

Further, according to the method of manufacturing the semiconductor device 10 of this embodiment, through formation of the gate electrode 22 so as to fill the lower portion of each gate groove 18 through intermediation of the gate insulating film 21, and, after that, formation of the buried insulating film 24 which covers the upper surface 22a of the gate electrode 22 so as to fill each gate groove 18, the gate electrode 22 does not protrude upward from the main surface 13a of the semiconductor substrate 13.

When this method is applied for manufacturing the DRAM as the semiconductor device 10, the bit line 34 and the capacitor 48 formed in a step subsequent to the step of forming the gate electrode 22 can be easily formed and, therefore, the semiconductor device 10 can be easily manufactured.

Note that, in this embodiment, a case is described by way of example in which a silicon oxide film (SiO₂ film) is used as the buried insulating film 24 and a silicon nitride film (SiN film) is used as the mask insulating film 26. However, a silicon nitride film (SiN film) may be used as the buried insulating film 24 and a silicon oxide film (SiO₂ film) may be used as the mask insulating film 26.

In this case, in the step illustrated in FIG. 15A and FIG. 15B, when the contact hole 41 is formed, the silicon nitride film (SiN film) as the buried insulating film 24 functions as an etching stopper, and thus, the contact hole 41 does not expose the upper surface 22a of the gate electrode 22. Therefore, electric conduction between the capacitor contact pad 44 and the gate electrode 22 via the capacitor contact plug 42 formed in the contact hole 41 may be prevented.

### Second Embodiment

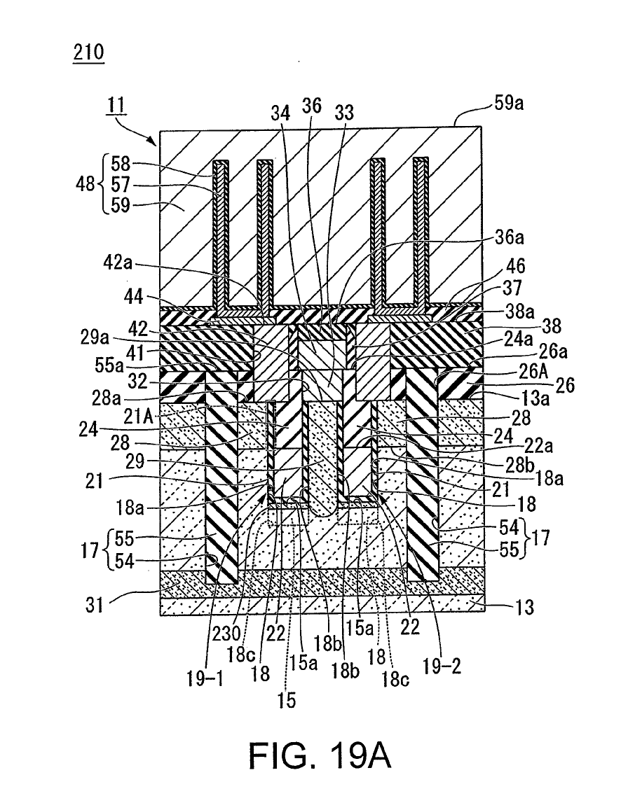

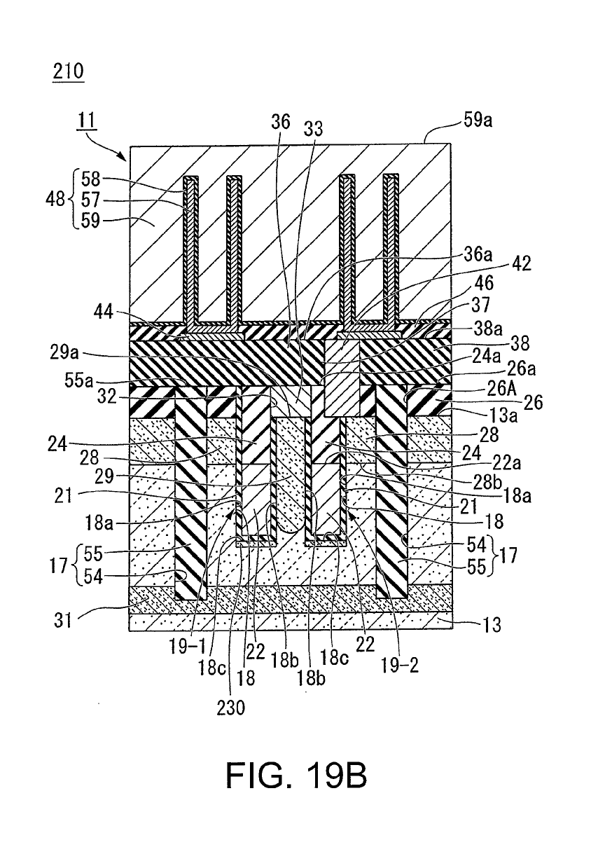

Next, a memory cell array provided in a semiconductor device according to a second embodiment of this invention and a method of manufacturing the memory cell array are described in detail with reference to FIG. 19A and FIG. 19B.

As illustrated in FIG. 19A and FIG. 19B, a structure of a semiconductor device 210 according to the second embodiment is different from the above-mentioned structure of the semiconductor device 10 according to the first embodiment in that the semiconductor device 210 illustrated in FIGS. 19A and 19B includes, as a first carrier capture region 230, the carrier capture region 30 mentioned in conjunction with the first embodiment and a second carrier capture region 31. Other points of the structure are the same as those of the first embodiment. Therefore, with regard to the structure of the semiconductor device and the method of manufacturing the same according to this embodiment, like reference symbols are used to designate like or identical members in the first embodiment and description thereof is omitted.

As illustrated in FIG. 19A and FIG. 19B, the second carrier capture region 31 is a carrier capture region for causing the electrons to disappear. Specifically, the second carrier capture region 31 is provided in the semiconductor substrate 13 (for example, a neutral region in a P-well), and is located at a portion deeper than the first carrier capture region 230 and the second diffusion region 29 from the surface of the semiconductor substrate 13.

Here, the depth of the second carrier capture region 31 from the surface of the semiconductor substrate 13 is not particularly limited insofar as the second carrier capture region 31 is deeper than a lower end of a depletion layer which is formed immediately below the gate electrode 22 when the gate electrode 22 is turned on and turned off. More specifically, the second carrier capture region 31 may be, for example, 0.3 μm to 0.5 μm deep from the surface of the semiconductor substrate 13.

Further, it is preferable that the width of the second carrier capture region 31 in a depth direction be 50 nm to 1,000 nm. Note that, an element which is of the same kind as that used in the first carrier capture region 230 may also be applied to the second carrier capture region 31.

Therefore, when the gate electrode 22 which is opposed to the carrier capture region via the gate insulating film 21 changes abruptly from the ON state to the OFF state, even when electrons released from the inversion layer formed on the surface of the active region 16 to be the gate interface into the semiconductor substrate 13 move the semiconductor substrate 13 through a region which is placed at a position deeper than the first carrier capture region 230 and the second diffusion region 29, the second carrier capture region 31 may effectively capture the electrons, and a level in the second carrier capture region 31 functions as a center of recombination. Therefore, in comparison with the case where only the first carrier capture region 230 is included, electrons can disappear more effectively.

The method of manufacturing the semiconductor device 210 according to the second embodiment includes, in addition to the steps in the method of manufacturing the semiconductor device 10 according to the above-mentioned first embodiment, a step of forming the semiconductor substrate 13 to be used in the step illustrated in FIG. 3A to FIG. 3D.

In the step of forming the semiconductor substrate 13 according to the second embodiment, when the second carrier capture region 31 which is deeper than the lower end of the depletion layer formed below the gate electrode 22 described above is, for example, 0.3 μm to 0.5 μm deep from the surface of the semiconductor substrate 13, the level is formed at a location which is 0.3 μm to 0.5 μm deep from the surface of the semiconductor substrate 13.

More specifically, the semiconductor substrate 13 is formed by epitaxially growing silicon on a surface of a substrate formed by a Czochralski (CZ) method (hereinafter, simply referred to as “CZ substrate”). For example, by epitaxially growing silicon at a thickness of 0.3 μm to 0.5 μm on the CZ substrate, the level at an interface between the CZ substrate and the epitaxially grown layer is matched with the same level as the neutral region in the P-well. This enables formation of the semiconductor substrate (namely, the CZ substrate) 13 in which the second carrier capture region 31 is in advance provided at the location which is 0.3 μm to 0.5 μm deep from the surface of the semiconductor substrate 13.

Further, when the amount of extinction electrons should be increased due to the second carrier capture region 31, it is preferable that an epitaxial layer which contains carbon or germanium is grown on the CZ substrate and after the SiC layer or the SiGe layer is formed at a thickness of, for example, about 50 nm to 500 nm, silicon may be epitaxially grown to a thickness of 0.3 μm to 0.5 μm.

As described above, according to the semiconductor device 210 according to the second embodiment, it is possible to obtain an effect similar to that of the above-mentioned first embodiment. Furthermore, the gate electrode 22 is opposed to the carrier capture region with the gate insulating film 21 interposed between the gate electrode 22 and the carrier capture region and is located at a position deeper than the first carrier capture region 230 and the second diffusion region 29. In this structure, it is assumed that the gate electrode 22 changes abruptly from the ON state to the OFF state and electrons released from the inversion layer formed on the surface of the active region 16 to be the gate interface move a region in the semiconductor substrate 13. In this event, the second carrier capture region 31 is effectively operable to capture the electrons. This is because both the first carrier capture region 230 and the second carrier capture region 31 are provided, and thus, the level in those carrier capture regions functions as a center of recombination. Therefore, electrons which are a cause of a disturb failure can quickly and effectively disappear. Accordingly, the above-mentioned disturb failure can be more effectively avoided.

Further, according to the method of manufacturing the semiconductor device 210 according to the second embodiment, through epitaxial growing of silicon on the CZ substrate, the level at the interface between the CZ substrate and the epitaxially grown layer may be easily adjusted to the same as that in the neutral region in the P-well. This enables easy formation of the semiconductor substrate 13 in which the second carrier capture region 31 is in advance provided at a desired depth from the surface of the semiconductor substrate 13.

Preferred exemplary embodiments according to this invention are described in detail in the above. However, this invention is not limited to those embodiments but may be modified and changed without departing the scope and spirit of this invention.

For example, each of the semiconductor substrate 13 and the first and the second diffusion regions may be used in an inverse conductive type mentioned in conjunction with the first and the second embodiments.

In the above-mentioned methods of manufacturing the semiconductor devices 10 and 210 according to the first and second embodiments, the carrier capture region 30 (first carrier capture region 230) is formed by ion implantation before the gate insulating film 21 is formed, but the carrier capture region 30 may be formed by ion implantation after the gate insulating film 21 is formed.

Here, when the ion implantation for forming the level is carried out after the gate insulating film 21 is formed, a thickness of the gate insulating film 21 is kept unchanged, and thus, the characteristics of the cell transistor may be easily adjusted. However, since a defect level might appear in the gate insulating film 21, the reliability of the gate insulating film 21 may be deteriorated. Therefore, in either of two cases in which carbon is selected and fluorine is selected as the element to be implanted, it is preferable that the dose be 5E14 atoms/cm² or lower.

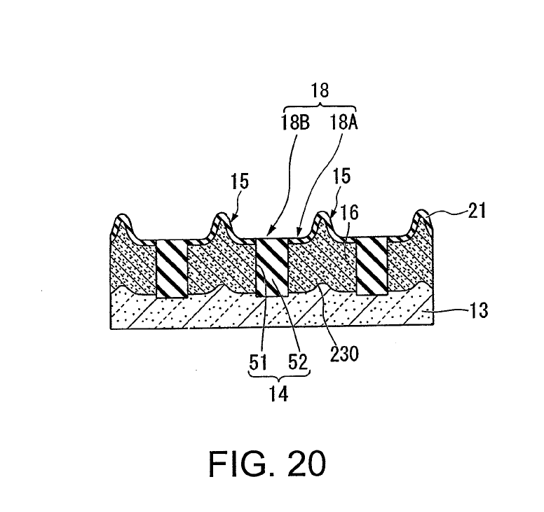

Further, when the ion implantation is carried out after the gate insulating film 21 is formed, it is preferable that the element for forming the level is implanted in the entirety of the fin portion 15 as illustrated in FIG. 20. In this event, it is also preferable that the energy for the ion implantation is set to be a little higher (more specifically, for example, 15 keV to 20 keV) so that ions are implanted in the entirety of the fin portion 15 having a height of 10 nm to 40 nm.

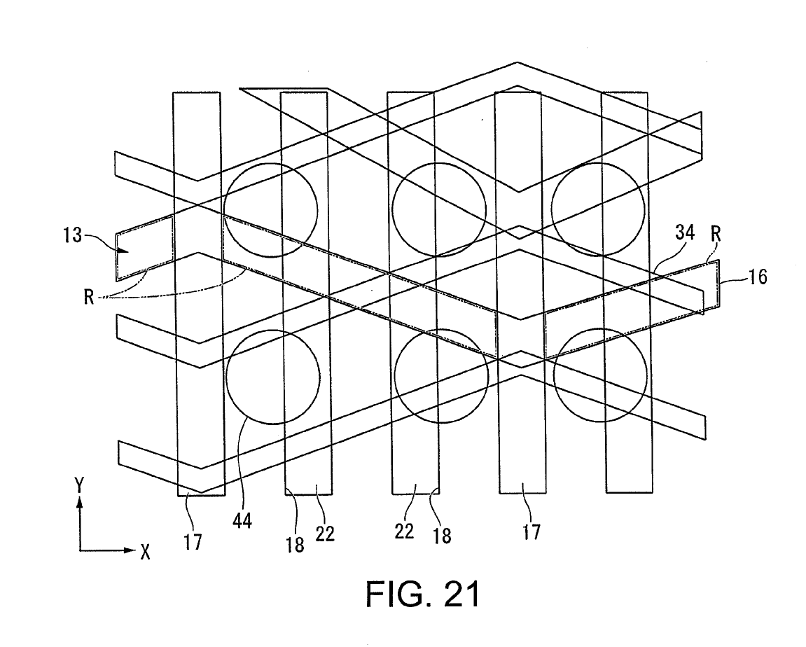

Further, FIG. 21 is a plan view illustrating another exemplary layout of a memory cell array which is applicable to the semiconductor device as an embodiment to which this invention is applied. In FIG. 21, like reference symbols are used to designate like or identical members in the structure illustrated in FIG. 1.

The semiconductor device 10 of the above-mentioned embodiment may be applicable to the layout illustrated in FIG. 21 in which the active regions 16 and the bit lines 34 are in a zigzag pattern.

This invention is applicable to a semiconductor device and a method of manufacturing the same.

What is claimed is:

1. A semiconductor device, comprising:
a semiconductor substrate;
a plurality of first isolation regions which are formed in the semiconductor substrate and extended in a first direction and each of which defines an active region having a plurality of element regions;
a gate groove which is provided in a surface of the semiconductor substrate and extended in a second direction intersecting the plurality of first isolation regions and the active regions, the gate groove comprising a first side surface and a second side surface opposed to the first side surface, and a bottom portion;
a fin portion formed by protruding a part of the active region from the bottom portion of the gate groove, by providing, in the gate groove, a first groove portion formed in the active region and a second groove portion which is formed in the first isolation regions and which is deeper than the first groove portion, and by making a depth of a portion of the first groove portion opposite to the second groove portion substantially flush with a depth of the second groove portion;
a gate insulating film which covers the gate groove and a surface of the fin portion;
a gate electrode which straddles the fin portion via the gate insulating film and which is embedded within a lower portion of the gate groove;
a first diffusion region provided in the semiconductor substrate so that the first diffusion region is located on the first side surface of each gate groove and covers an upper portion of the gate insulating film;
a second diffusion region provided in the semiconductor substrate so that the second diffusion region is located on the second side surface and covers a part of the gate insulating film other than a lower end portion of the gate insulating film; and
a carrier capture region formed in the surface of the fin portion so that the carrier capture region is opposed to the gate electrode with the gate insulating film interposed between the gate electrode and the carrier capture region.

2. A semiconductor device according to claim 1, wherein the carrier capture region is provided under the entirety of the fin portion.

3. A semiconductor device according to claim 1,
wherein the carrier capture region comprises a first carrier capture region, and
wherein the semiconductor device further comprises a second carrier capture region provided at a position deeper than the first carrier capture region and the second diffusion region from a surface of the semiconductor substrate.

4. A semiconductor device according to claim 1,
wherein the bottom portion of the gate groove has a depth of 150 nm to 200 nm from the surface of the semiconductor substrate, and
wherein a height from the bottom portion of the gate groove to an upper portion of the fin portion is 10 nm to 40 nm.

5. A semiconductor device according to claim 1, wherein the second diffusion region is shallower than the bottom portion of the gate groove and is deeper than an upper portion of the fin portion.

6. A semiconductor device according to claim 1,
wherein the gate groove is structured by two gate grooves provided so that the second side surfaces thereof are opposed to each other, and
wherein the second diffusion region is provided in a part of the semiconductor substrate between the two gate grooves.

7. A semiconductor device according to claim 1, wherein the first diffusion region is provided shallower by 5 nm to 10 nm with respect to an upper surface of the gate electrode.

8. A semiconductor device according to claim 1,
wherein the fin portion has an upper portion extending in the first direction, and
wherein the upper portion has both ends provided to reach the first side surface and the second side surface of the first groove portion.

9. A semiconductor device according to claim 1, further comprising a plurality of second isolation regions, which are located in the semiconductor substrate so as to extend in the second direction intersecting the first direction and which partition each active region into the plurality of the element regions.

10. A semiconductor device according to claim 1, further comprising a bit line, which is electrically connected to the second diffusion region and which extends in a direction intersecting the gate electrode.

11. A semiconductor device according to claim 1, further comprising:
a buried insulating film provided so that the buried insulating film covers an upper surface of the gate electrode and is embedded into the gate groove;
an interlayer insulating film provided on the buried insulating film;
a contact plug formed through the buried insulating film and the interlayer insulating film so as to be held in contact with an upper surface of the first diffusion region;
a capacitor contact pad provided on the interlayer insulating film and held in contact with an upper surface of the contact plug; and
a capacitor provided on the capacitor contact pad.

12. A semiconductor device, comprising:
a semiconductor substrate;
a plurality of first isolation regions which are formed in the semiconductor substrate and which extend in a first direction so as to define an active region having a plurality of element regions;
a plurality of second isolation regions which are formed in the semiconductor substrate and which extend in a second direction intersecting the first direction so as to partition the active region into the plurality of element regions;
a pair of gate grooves which are provided in a surface of the semiconductor substrate and between adjacent two of the plurality of second isolation regions and which extend in the second direction intersecting the plurality of first isolation regions and the active region, the pair of gate grooves each comprising:
a first side surface and a second side surface, which are opposed to each other; and
a bottom portion;
a fin portion formed by protruding a part of the active region from the bottom portion of the gate groove, by providing, in the gate groove, a first groove portion formed in the active region and a second groove portion which is formed in the first isolation regions and which is deeper than the first groove portion, and by making a depth of a portion of the first groove portion opposite to the second groove portion substantially flush with a depth of the second groove portion;
a gate insulating film which covers each of the pair of gate grooves and a surface of the fin portion;
a pair of gate electrodes each formed so that each gate electrode straddles the fin portion via the gate insulating film and is embedded within lower portions of the pair of gate grooves, respectively;
two first diffusion regions each provided in an upper surface of the semiconductor substrate in a part between corresponding one of the adjacent two of the plurality of second isolation regions and corresponding one of the pair of gate grooves, each of the two first diffusion regions being connected to a capacitor;
one second diffusion region provided in the semiconductor substrate in a part between the pair of gate grooves arranged so that the second side surfaces thereof are opposed to each other, the one second diffusion region being connected to a bit line; and
a carrier capture region provided in the surface of the fin portion so as to be opposed to corresponding one of the pair of gate electrodes across the gate insulating film,
wherein each of the plurality of element regions comprises:
a first transistor comprising at least:
one of the pair of gate electrodes;
the fin portion; and
one of the two first diffusion regions; and
a second transistor comprising at least:
another of the pair of gate electrodes;
the fin portion; and
another of the two first diffusion regions,
the first transistor and the second transistor sharing the one second diffusion region,
wherein the bottom portion of the each of the pair of gate grooves has a depth of 150 nm to 200 nm from the surface of the semiconductor substrate, and
wherein a height from the bottom portion of the each of the pair of gate grooves to an upper portion of the fin portion is 10 nm to 40 nm.

13. A semiconductor device according to claim 12, wherein the carrier capture region is provided in the entire fin portion.

14. A semiconductor device according to claim 12,
wherein the carrier capture region comprises a first carrier capture region, and
wherein the semiconductor device further comprises a second carrier capture region provided at a position deeper than the first carrier capture region and the one second diffusion region from a surface of the semiconductor substrate.

15. A semiconductor device according to claim 12, wherein the one second diffusion region is shallower than the bottom portion of the each of the pair of gate grooves and is deeper than the upper portion of the fin portion.

16. A method of manufacturing a semiconductor device, comprising:
forming, in a semiconductor substrate, a plurality of first isolation grooves extending in a first direction, and filling the plurality of first isolation grooves with first isolation insulating films, respectively, to thereby form a plurality of first isolation regions and to define an active region having a plurality of element regions;
forming, in the semiconductor substrate, a plurality of second isolation grooves extending in a second direction intersecting the first direction, and filling the plurality of the second isolation grooves with second isolation insulating films, respectively, to thereby form a plurality of second isolation regions and to define the plurality of element regions;
forming, in the semiconductor substrate, a pair of gate grooves between two adjacent ones of the plurality of the second isolation regions so as to extend in the second direction intersecting the plurality of first isolation regions and the active region, the pair of gate grooves being formed so that each of the pair of gate grooves comprises a first side surface and a second side surface opposed to the first side surface and a bottom portion and so that the second side surfaces of the pair of the gate grooves are opposed to each other;
forming a fin portion in a manner that a part of the active region protrudes from the bottom portion of the each of the pair of gate grooves;
performing ion implantation of a capture level-formable element in the bottom portion of the each of the pair of gate grooves, to thereby form a carrier capture region in at least a surface of the fin portion;
forming a gate insulating film for covering each of the pair of gate grooves and the surface of the fin portion;
forming a gate electrode so as to straddle the fin portion and to embed a lower portion of the each of the pair of gate grooves via the gate insulating film;
forming a buried insulating film so as to cover an upper surface of the gate electrode and to fill the each of the pair of gate grooves;
forming a pair of first diffusion regions each in an upper surface of the semiconductor substrate in a part between corresponding one of the two adjacent ones of the plurality of second isolation regions and corresponding one of the pair of gate grooves, each of the pair of first diffusion regions being formed so as to cover an upper portion of the gate insulating film, the upper portion being arranged on the first side surface; and
performing selective ion implantation of impurities which have a conductivity type different from a conductivity type of the semiconductor substrate, into a part of the semiconductor substrate between the pair of gate grooves formed so that the second side surfaces thereof are opposed to each other, to thereby form a second diffusion region.

17. A method of manufacturing a semiconductor device according to claim 16, further comprising forming the semiconductor substrate by epitaxially growing silicon on a surface of a substrate formed by a Czochralski method.

18. A method of manufacturing a semiconductor device according to claim 16,
wherein the forming of the pair of gate grooves comprises forming the each of the pair of gate grooves so that the bottom portion thereof has a depth of 150 nm to 200 nm from a surface of the semiconductor substrate, and wherein the forming of the fin portion comprises forming the fin portion so that a height thereof from the bottom portion of the each of the pair of gate grooves to an upper portion of the fin portion is 10 nm to 40 nm.

19. A method of manufacturing a semiconductor device according to claim 16, wherein the forming of the second diffusion region comprises forming the second diffusion region to be shallower than the bottom portion of the each of the pair of gate grooves and to be deeper than an upper portion of the fin portion.

20. A method of manufacturing a semiconductor device according to claim 16, further comprising:
forming a bit line above the second diffusion region formed at the part of the semiconductor substrate between the pair of gate grooves, the bit line extending in a direction intersecting the gate electrode and being electrically connected to the second diffusion region;
forming an interlayer insulating film on the buried insulating film;
forming, through the buried insulating film and the interlayer insulating film, a contact plug held in contact with an upper surface of the first diffusion region;
forming a capacitor contact pad on the interlayer insulating film, the capacitor contact pad being held in contact with an upper surface of the contact plug; and
forming a capacitor on the capacitor contact pad.
